(19) United States
(12) Patent Application Publication
(10) Pub. No.: US 2013/0157466 A1
(43) Pub. Date: Jun. 20, 2013

(54) SILICON NITRIDE FILMS FOR SEMICONDUCTOR DEVICE APPLICATIONS

(71) Applicants: Keith Fox, Tigard, OR (US); Dong Niu, West Linn, OR (US); Joseph L. Womack, Tigard, OR (US); Mandyam Sriram, Beaverton, OR (US); George Andrew Antonelli, Portland, OR (US); Bart J. van Schravendijk, Sunnyvale, CA (US); Jennifer O'Loughlin, Portland, OR (US)

(72) Inventors: Keith Fox, Tigard, OR (US); Dong Niu, West Linn, OR (US); Joseph L. Womack, Tigard, OR (US); Mandyam Sriram, Beaverton, OR (US); George Andrew Antonelli, Portland, OR (US); Bart J. van Schravendijk, Sunnyvale, CA (US); Jennifer O'Loughlin, Portland, OR (US)

(21) Appl. No.: 13/766,696

(22) Filed: Feb. 13, 2013

Related U.S. Application Data
(63) Continuation-in-part of application No. 12/970,853, filed on Dec. 16, 2010.
(60) Provisional application No. 61/612,872, filed on Mar. 19, 2012.
(60) Provisional application No. 61/598,814, filed on Feb. 14, 2012.
(60) Provisional application No. 61/394,707, filed on Oct. 19, 2010.
(60) Provisional application No. 61/382,465, filed on Sep. 13, 2010.
(60) Provisional application No. 61/382,468, filed on Sep. 13, 2010.
(60) Provisional application No. 61/317,656, filed on Mar. 25, 2010.

(51) Int. Cl. H01L 21/306

(52) U.S. Cl. CPC H01L 21/30604
USPC 438/694; 118/704

(57) ABSTRACT

The embodiments herein relate to plasma-enhanced chemical vapor deposition methods and apparatus for depositing silicon nitride on a substrate. The disclosed methods provide silicon nitride films having wet etch rates (e.g., in dilute hydrofluoric acid or hot phosphoric acid) suitable for certain applications such as vertical memory devices. Further, the methods provide silicon nitride films having defined levels of internal stress suitable for the applications in question. These silicon nitride film characteristics can be set or tuned by controlling, for example, the composition and flow rates of the precursors, as well as the RF power supplied to the plasma and the pressure in the reactor. In certain embodiments, a boron-containing precursor is added.

### CROSS REFERENCE TO RELATED APPLICATIONS

This application claims benefit of U.S. Provisional Patent Application Ser. No. 61/612,872, titled “SMOOTH SILICON—CONTAINING FILMS,” and filed on Mar. 19, 2012 and U.S. Provisional Patent Application Ser. No. 61/598,814, titled “SMOOTH SILICON—CONTAINING FILMS,” and filed on Feb. 14, 2012, both of which are incorporated herein by reference in their entireties and for all purposes. This application is also a continuation-in-part of U.S. patent application Ser. No. 12/970,853, titled “SMOOTH SILICON—CONTAINING FILMS,” filed on Dec. 16, 2010, which claims benefit of each of the following U.S. provisional patent applications: U.S. Provisional Patent Application Ser. No. 61/394,707, titled “IN-SITU PLASMA-ENHANCED CHEMICAL VAPOR DEPOSITION OF FILM STACKS,” and filed on Oct. 19, 2010; U.S. Provisional Patent Application Ser. No. 61/382,465, titled “IN-SITU PLASMA-ENHANCED CHEMICAL VAPOR DEPOSITION OF FILM STACKS,” and filed on Sep. 13, 2010; U.S. Provisional Patent Application Ser. No. 61/382,468, titled “SMOOTH SILANE-BASED FILMS,” and filed on Sep. 13, 2010; and U.S. Provisional Patent Application Ser. No. 61/317,656, titled “IN-SITU PLASMA-ENHANCED CHEMICAL VAPOR DEPOSITION OF FILM STACKS,” and filed on Mar. 25, 2010, each of which is incorporated by reference in its entirety and for all purposes.

### BACKGROUND

One material that is commonly used in the formation of semiconductor devices is silicon nitride. In some applications, a silicon nitride layer is used as a sacrificial layer that is wholly or partially etched away at some point after it is deposited. Because the silicon nitride material is etched away, it is desirable in these applications for the material to have a controlled, high wet etch rate. Furthermore, because subsequent semiconductor processing operations will often expose the material to high temperatures, it is desirable for the silicon nitride material to exhibit good thermal stability. A material is more thermally stable if it does not out-gas or produce significant uncontrolled changes in internal stress when exposed to post-deposition high temperature processing operations. Further, when the silicon nitride material is used in a stack with layers of other materials (e.g., silicon oxide layers), it may be desirable for the silicon nitride material to have properties that are tunable such that the resulting stack is thermally stable and may be properly and rapidly etched. To this end, it may be desirable for the silicon nitride material to exhibit certain properties (e.g., internal stress levels) that counteract the properties of other layers in the stack. As such, there exists a need for a method and apparatus for depositing silicon nitride in a manner that allows the internal stress and/or etch rate of the silicon nitride to be tuned to particular values.

### SUMMARY

In one aspect of the embodiments herein, a method is disclosed for forming a silicon nitride film on a substrate in a plasma-enhanced chemical vapor deposition apparatus, including flowing a silicon-containing reactant, a nitrogen-containing reactant and a boron-containing reactant through the chemical vapor deposition apparatus, where the ratio of the flow rates of the silicon- to nitrogen-containing reactant is about 0.02 or less; generating or maintaining a plasma in the apparatus; and depositing the silicon nitride film on the substrate.

The silicon-containing reactant may be silane, disilane, trisilane or alkyl silane in certain cases. The nitrogen-containing reactant may be ammonia, hydrazine or nitrogen in certain cases. In some embodiments, the boron-containing reactant may be diborane or trimethyl borate. The flowing operation may include flowing diborane at a rate of about 4-15 sccm. In some cases, the silicon-containing reactant is silane and the boron-containing reactant is diborane, and the flowing operation is conducted such that the ratio of the flow rates of silane to diborane is about 3 to 20 (i.e., a ratio of about 0.15). In certain implementations, the ratio of the flow rates of the silane to diborane is between about 0.02-0.35, for example between about 0.1-0.2. Some embodiments employ an inert carrier gas to aid in flowing one or more of the reactants. For example, the diborane may be flowed into the apparatus in an inert gas carrier. In certain cases, the inert gas is nitrogen. In other cases, the inert gas may be hydrogen or argon.

Some embodiments employ a low frequency and high frequency power to generate and maintain the plasma, with a low frequency power provided at about 0-300 Watts per 300 mm wafer. In some cases, the low frequency power is provided at or below about 100 Watts per 300 mm wafer, for example at or below about 75 Watts per 300 mm wafer. The high frequency power may be provided in certain cases between about 100-750 Watts per 300 mm wafer, for example between about 100-500 Watts per 300 mm wafer. In some of the embodiments herein, the pressure in the apparatus is maintained between about 0.5-8 Torr while depositing the silicon nitride film on the substrate, for example between about 1-6 Torr. During the depositing operation in many implementations, the silicon nitride film is deposited to a thickness of between about 10-100 nm.

In some implementations, the deposited silicon nitride film etches at a rate of at least about 20 Ångstroms/minute when exposed to aqueous hydrofluoric acid provided in a volume ratio of 100 units water to 1 unit standard 50% hydrofluoric acid at 20° C. Some embodiments also include selecting an amount of internal stress for the silicon nitride film and selecting process parameters for depositing the silicon nitride film with the selected amount of internal stress. In some cases, the depositing is conducted under conditions that produce the silicon nitride film with a tensile internal stress. The tensile stress may be between about 400-600 MPa in certain implementations. The deposited silicon nitride film may include between about 1-15 atomic percent boron in some embodiments. In certain implementations, the silicon nitride film has an average roughness of less than about 6 Ångstroms as measured on the substrate. In some cases the silicon nitride film is smoother, having an average roughness of less than about 4.5 Ångstroms as measured on the substrate. The embodiments herein may further include heating the substrate with deposited silicon nitride film to a temperature of at least about 400° C. In certain implementations the substrate with the deposited film is heated to a temperature between about 400-650° C., for example between about 450-600° C.

The embodiments herein may also include forming a stack with alternating layers of an oxide and the deposited silicon nitride. In some implementations the stack contains at least about 10 layers of the silicon nitride film. Further, in some cases the stack contains at least about 50 layers of the silicon nitride film. After a stack is formed, the stack may be wet etched to form a fishbone shaped structure having recesses. The fishbone shaped structure may have “bones” of silicon oxide material and recesses where the silicon nitride material has been etched away. In certain embodiments, the fishbone shaped structure may be used to form a vertical memory device. For example, the recesses formed by etching the silicon nitride film may be filled with material that is used to form a capacitor. In some cases the recesses are filled with tungsten. Generally, the capacitor will be at least partially inside the recesses formed by wet etching the silicon nitride.

In another aspect of the disclosed embodiments, a method is provided for forming a film stack including a silicon nitride film and a second film having a different composition from the silicon nitride film on a substrate, including depositing the silicon nitride film on the substrate by plasma-enhanced chemical vapor deposition while flowing a silicon-containing reactant, a nitrogen-containing reactant, and a boron-containing reactant through the plasma-enhanced chemical vapor deposition apparatus, where the silicon nitride film has a thickness of between about 10-100 nm; depositing the second film on the silicon nitride film, where the second film has a thickness of between about 10-100 nm; and repeating the two depositing operations at least twice to form the film stack. In some implementations, the depositing silicon nitride film operation is conducted such that the ratio of flow rates of the silicon- to nitrogen-containing reactants is about 0.02 or less. In certain embodiments, the second film is a silicon oxide film. The silicon oxide film, in some cases, is formed by a thermal process. The depositing steps may be repeated various times to form the film stack, for example, these steps may be repeated at least 10 times, or in some cases at least 50 times to form the film stack. Furthermore, the silicon nitride may be wet etched from the stack to form a fishbone shaped structure having recesses. As noted above, the fishbone shaped structure may be used to form a vertical memory device. For example, some embodiments include forming capacitors at least partially inside the recesses formed by wet etching silicon nitride.

In some implementations, the method of forming the stack may also include applying photoresist to the substrate; exposing the photoresist to light; patterning the resist with a pattern and transferring the pattern to the substrate; and selectively removing the photoresist from the substrate.

In another aspect of the disclosed embodiments, a plasma-enhanced chemical vapor deposition apparatus configured to deposit a film stack on a substrate is provided. The apparatus includes a process station; a first reactant feed for supplying a silicon-containing reactant to the process station; a second reactant feed for supplying a co-reactant to the process station; a plasma source; and a controller configured to control the apparatus to maintain a plasma and process gas flow conditions, the controller having instructions for depositing a silicon nitride film on the substrate by plasma-enhanced chemical vapor deposition while flowing the silicon-containing reactant, a nitrogen-containing reactant, and a boron-containing reactant through the plasma-enhanced chemical vapor deposition apparatus containing the substrate, where the silicon nitride film has a thickness of between about 10-100 nm, further instructions for depositing the second film on the silicon nitride film, where the second film has a thickness of between about 10-100 nm. In some embodiments, the controller also has instructions for repeating the depositing operations at least twice to form the film stack. In certain implementations, the controller has instructions to repeat the depositing operations more than twice, for example ten times or fifty times, to form the stack. The plasma source may be a capacitively-coupled plasma source in certain embodiments.

In some implementations, the controller instructions for depositing the silicon oxide film may include instructions for providing a ratio of flow rates of the silicon- to nitrogen-containing reactants at about 0.02 or less. In some implementations the second film is a silicon oxide film. The controller instructions may further include instructions for forming the silicon oxide film by a thermal process. In certain embodiments, the boron-containing reactant is diborane, and the controller is configured to flow the diborane into the process station at a rate of between about 4-15 sccm. In certain cases where the boron-containing reactant is diborane and the silicon-containing reactant is silane, the controller may be configured to flow the silane and diborane at a flow rate ratio of about 3 to 20 silane to diborane (i.e., a ratio of about 0.15). In certain implementations, the controller is configured to maintain the ratio of the flow rates of the silane to diborane between about 0.02-0.35, for example between about 0.1-0.2. In some embodiments, the controller also has instructions for generating and maintaining a plasma using the plasma source. For example, the instructions may include instructions for generating low frequency and high frequency power, with the low frequency power provided at or below about 150 Watts per 300 mm wafer. As a further example, the instructions may include instructions for generating high frequency power at about 100-750 Watts per 300 mm wafer. In some implementations, the controller may further have instructions for maintaining a pressure of between about 0.5-8 Torr in the process station while depositing the silicon nitride film on the substrate.

In an additional aspect of the disclosed embodiments, a system is provided including the apparatus described above (including a process station; a first reactant feed for supplying a silicon-containing reactant to the process station; a second reactant feed for supplying a co-reactant to the process station; a plasma source; and a controller configured to control the apparatus to maintain a plasma and process gas flow conditions, the controller having instructions for depositing a silicon nitride film on the substrate by plasma-enhanced chemical vapor deposition while flowing the silicon-containing reactant, a nitrogen-containing reactant, and a boron-containing reactant through the plasma-enhanced chemical vapor deposition apparatus containing the substrate, where the silicon nitride film has a thickness of between about 10-100 nm, further instructions for depositing the second film on the silicon nitride film, where the second film has a thickness of between about 10-100 nm) and a stepper tool.

These and other features of the disclosure will be described in more detail below with reference to the drawings.

### BRIEF DESCRIPTION OF THE DRAWINGS

FIG. 1 depicts a flowchart of one disclosed embodiment for forming a unit layer of silicon nitride on a substrate.

FIG. 2 depicts a flowchart of a disclosed embodiment for forming an etched silicon nitride/silicon oxide stack.

FIG. 3 schematically shows a process station according to an embodiment of the present disclosure.

FIG. 4 schematically shows a multi-station process tool according to an embodiment of the present disclosure.

FIG. 5 schematically shows another multi-station process tool according to an embodiment of the present disclosure.

FIG. 6 schematically shows another multi-station process tool according to an embodiment of the present disclosure.

FIG. 7 depicts fourier transform infrared spectroscopy (FTIR) spectra for silicon nitride films produced using (1) a baseline process, (2) a baseline process with low diborane, and (3) a baseline process with high diborane.

FIGS. 8A-B show the bow shift ratio (8A) and wet etch rate ratio (8B) vs. the ratio of diborane to silane in the process gases.

FIG. 8C shows the reaction parameters and resulting film properties for the films characterized in FIGS. 8A-B.

FIG. 9 shows the FTIR spectra for films produced using (1) a baseline process, and (2) a low-silane process.

FIGS. 10A-C show the bow shift ratio (10A), wet etch rate ratio (10B) and surface roughness (8C) vs. the amount of silane flow in the process gases.

FIG. 10D shows the reaction parameters and resulting film properties for the films characterized in FIGS. 10A-C.

FIG. 11A depicts the wet etch rate ratio vs. as-deposited stress values for several films produced according to a low silane process.

FIG. 11B shows the reaction parameters and resulting film properties for the films characterized in FIG. 11A.

FIG. 12 shows the bow shift ratio vs. as-deposited stress for films produced according to a low silane process.

FIG. 13 depicts the FTIR spectra for silicon nitride films produced using (1) a low silane/low ammonia process, (2) a low silane/mid-level ammonia process, and (3) a low silane/high ammonia process.

FIGS. 14A-C show the bow shift ratio (14A), wet etch rate ratio (14B) and surface roughness (14C) vs. the amount of ammonia flow in the process gases.

FIG. 14D shows the reaction parameters and resulting film properties for the films characterized in FIGS. 14A-C.

FIG. 15 shows the FTIR spectra for silicon nitride films produced using (1) a low silane/high diboron process, (2) a low silane/low diboron process, and (3) a low silane process with no diboron.

FIGS. 16A-C depict the bow shift ratio (16A), wet etch rate ratio (16B) and surface roughness (16C) vs. the ratio of diboron to silane in the process gases.

FIG. 16D shows the reaction parameters and resulting film properties for the films characterized in FIGS. 16A-C.

FIG. 17 shows the FTIR spectra for silicon nitride films produced using a low silane/high diborane process, both (1) pre-anneal and (2) post-anneal.

FIG. 18 show the FTIR spectra for silicon nitride films produced using low levels of silane, mid-levels of diborane, and increasing levels of ammonia.

FIGS. 19A-C show the bow shift ratio (19A), wet etch rate ratio (19B), and surface roughness (19C) vs. amount of ammonia in the process gases.

FIG. 19D shows the reaction parameters and resulting film properties for the films characterized in FIGS. 19A-C.

FIGS. 20A-B depict the bow shift ratio (20A) and wet etch rate ratio (20B) vs. the ratio of diborane to silane in the process gases.

FIG. 20C shows the reaction parameters and resulting film properties for the films characterized in FIGS. 20A-20B.

FIG. 21 shows the bow shift ratio vs. as-deposited stress for films produced with diborane.

FIG. 22 depicts a stack of alternating silicon nitride and silicon oxide layers used in some of the experiments herein.

FIG. 23A depicts an etched multi-layer stack produced with silicon oxide layers and (1) baseline silicon nitride layers, (2) high ammonia:silane silicon nitride layers, and (3) higher ammonia:silane silicon nitride layers.

FIG. 23B shows the reaction parameters and resulting film properties for the film layers shown in FIG. 23A.

FIG. 24A depicts an etched multi-layer stack produced with silicon oxide layers and (1) baseline silicon nitride layers, (2) low diboron silicon nitride layers, and (3) higher diboron silicon nitride layers.

FIG. 24B shows the reaction parameters and resulting film properties for the film layers shown in FIG. 24A.

FIG. 25A shows a multi-layer stack produced with silicon oxide layers and (1) baseline silicon nitride layers, (2) high ammonia:silane/high diboron silicon nitride layers, and (3) high ammonia:silane/higher diboron silicon nitride layers.

FIG. 25B shows the reaction parameters and resulting film properties for the films characterized in FIG. 25A.

FIG. 26A shows a multi-layer stack with alternating silicon oxide and silicon nitride layers, and specifically shows the low thickness of silicon oxide removed during etching.

FIG. 26B shows the etch ratio and etch selectivity of the silicon oxide layers compared to (1) the baseline silicon nitride layers, and (2) the silicon boronitride layers.

FIG. 27A shows a multi-layer stack with alternating layers of silicon oxide with (1) silicon nitride, or (2) silicon boronitride, as used in some of the experiments herein.

FIG. 27B depicts data showing how different silicon nitride layers impact bow shift in large multi-layer stacks subjected to high processing temperatures.

FIG. 28 shows a micrograph of a fishbone structure used in certain vertical memory devices fabricated on semiconductor substrates.

### DETAILED DESCRIPTION

### Methods

Various embodiments presented herein are made with reference to a plasma enhanced chemical vapor deposition (PECVD) process that employs a silicon-containing reactant, a nitrogen-containing reactant and a boron-containing reactant. In some embodiments, silane and ammonia are used as reactant process gases. Nitrogen, hydrogen or a noble gas may be used as a carrier. For context, some embodiments are described with reference to a “baseline process”. In such a baseline process, silane and ammonia are delivered to a four station reactor (e.g., a Vector® Extreme or Vector® Express reactor from Lam Research, Inc. of Fremont, Calif.) where they are reacted to produce silicon nitride films on 300 mm wafers. It should be understood that the disclosed embodiments are not limited to 300 mm wafers. Wafers of other sizes such as 200 mm wafers, 450 mm wafers, etc. may be used as substrates. In some cases, as will be understood by those of skill in the art, process conditions will have to be scaled from those stated for 300 mm wafers when wafers of other sizes are used.

In the baseline process, silane is delivered at a flow rate of about 200 sccm (100% silane), ammonia is delivered at about 1140 sccm, and the nitrogen at about 9000 sccm. The pressure employed in the baseline process is about 2 Torr. Low frequency & high frequency RF power is provided to generate the plasma. The low frequency radio frequency (LF RF) power is provided at 400 kHz and about 0 to 150 Watts (about 0-40 W per 300 mm wafer). The high frequency radio frequency (HF RF) power is provided at 13.56 MHz and about 800 Watts (about 200 W per 300 mm wafer).

The baseline process is used to produce silicon nitride films. Unless otherwise clear from context, the term silicon nitride is intended to cover stoichiometric and non-stoichiometric solid compositions of primarily silicon and nitrogen. Silicon nitride films may have various morphologies, including varying degrees of crystallinity, roughness, etc. The general term silicon nitride also encompasses compositions that include elements other silicon and nitrogen. Frequently, some hydrogen is present in the composition. In various embodiments described herein, boron is added. Thus, unless otherwise specified, the term silicon nitride includes the silicon boronitrides described herein.

Disclosed improvements on the baseline process include (a) adding a boron containing precursor to the process gases, (b) lowering the concentration of silane in the process gas, and (c) a combination of (a) and (b). In certain embodiments, an improvement includes controlling the low frequency RF power between about 0-300 Watts per 300 mm wafer, or between about 0-100 Watts per 300 mm wafer. Processes falling within the scope of these improvements do not require the exact baseline conditions described above. For example, they may be practiced within a range of silane to ammonia flow ratios (e.g., about 0.007 to 0.2), and/or within a range of RF frequencies and powers (e.g., about 100 to 750 Watts per 300 mm wafer HFRF power at 13.56 MHz and about 0 to 300 Watts per 300 mm wafer LFRF power in a frequency range between 370 to 430 KHz), and/or within a range of pressures (e.g., about 0.5 to 6.0 Torr). The above ranges are provided for a 4-station PECVD chamber equipped for depositing films on 300 mm silicon wafers. The flow rates and powers may have to be scaled as appropriate for reactors of other sizes.

In various applications, a silicon nitride layer deposited as described herein is used as a sacrificial layer. In such applications, the silicon nitride layer may be partially or wholly removed by a wet etching process. Thus, the wet-etch rate of the deposited silicon nitride layer may be important for some applications. Examples of wet etchants include hydrofluoric acid (including buffered versions of the acid) and phosphoric acid.

For various applications, the silicon nitride layer should have good thermal stability. That is, it should not out-gas or produce significant uncontrolled changes in internal stress when exposed to post-deposition high temperature processing. The following description addresses certain experiments in which the wet-etch rate and/or the thermal stability of silicon nitride films are reported.

Additionally, various experiments are described in which the deposited silicon nitride films are subjected to a high temperature “anneal.” This anneal is intended to generally represent the high temperature processing that a silicon nitride layer would normally experience after it is deposited during fabrication of other components of a memory or logic device, for example. In many of the experiments described herein, a 750° C. anneal temperature is applied to the film for two hours. In practice, it is expected that post deposition processing may sometimes exceed this temperature, sometimes reaching 800° C. or even 850° C.

Generally, the disclosed embodiments employ plasma assisted deposition processes for forming a silicon nitride-containing film that includes some fraction of boron. The film is deposited in a process station that is configured to receive a process gas containing a silicon-containing reactant, a nitrogen-containing reactant, and a boron-containing reactant. The process gas containing these reactants may be mixed in the process station or premixed upstream before entering the process station. A plasma is generated and maintained and interacts with the process gas to facilitate deposition of the silicon nitride film on a substrate. A carrier gas may be used together with the silicon, nitrogen, and boron-containing reactant gases. In certain embodiments, the carrier gas is nitrogen, hydrogen, a noble gas such as argon, or a combination of these.

In certain embodiments, a relatively low fractional amount of the silicon-containing reactant is used. In some embodiments, the ratio of flow rates of the silicon-containing reactant to the nitrogen-containing reactant is about 0.02 or less.

In certain embodiments, the silicon-containing reactant is silane (SiH₄). In other embodiments, the silicon-containing reactant is a variant of silane such as disilane, trisilane, or an alkyl silane such as a mono, di-, tri-, or tetra substituted silane. The alkyl substitutions may include one, two, three, four, five, or six carbon atoms. Generally, the silicon-containing reactant is a gas at room temperature, however, in certain embodiments it may be delivered via a volatilizing carrier gas.

In certain implementations, the nitrogen-containing reactant is ammonia. However, other types of nitrogen-containing reactants may be employed. Examples include hydrazine, nitrous oxide, and elemental nitrogen in the presence of a strong plasma.

In various embodiments, the boron-containing reactant is diborane. Diborane is a liquid at room temperature. Therefore, it is typically delivered to the process station in a carrier gas such as argon, nitrogen or hydrogen. In some embodiments, it is provided at a molar concentration of about 5% diborane in argon. Other sources of boron may be used in some embodiments. These include, for example, alkyl substituted boranes such as trimethyl borane (TMB).

In various embodiments, the ratio of the silicon-containing reactant to the nitrogen-containing reactant is maintained at a relatively low level during deposition of the silicon nitride film. As mentioned, in some embodiments, the volumetric ratio of the silicon-containing reactant to the nitrogen-containing reactant is about 0.02 or less. In other embodiments, the ratio is even smaller, e.g., about 0.01 or less.

These ratios are appropriate for silane and ammonia as the silicon-containing and nitrogen-containing reactants, respectively. In cases where one of the reactants contains proportionately more silicon and/or nitrogen (on a molar basis) than a silane-ammonia mixture, these ratios may need to be adjusted to account for the different elemental amounts of silicon and/or nitrogen in the process gases. An example is the case of a process gas containing trisilane and ammonia.

The ratio of boron-containing reactant to silicon-containing reactant is typically relatively small. In certain embodiments, it is about 0.02 to about 0.1. This represents the volumetric ratio or flow rate ratio between the actual amount of boron-containing reactant and silicon-containing reactant. So, in the case of a 5% diborane process gas, the ratio is determined by considering only the diborane and not the carrier gas in which the diborane is provided. Further, the above ratios are appropriate for diborane and silane. The use of other silicon-containing and/or boron-containing reactants may require that these ratios be adjusted to account for the number of boron or silicon atoms in a molecule of each reactant.

The deposition conditions in the process station during formation of a silicon nitride film may be further characterized by the temperature, pressure, and plasma conditions. In certain embodiments, the pressure in the station during deposition is between about 0.5 and 8 Torr, or between about 1 and 6 Torr. In certain embodiments, the temperature of the substrate on which the silicon nitride film is formed is between about 400 and 650° C. or between about 450 and 600° C. The RF power delivered to the process station during deposition may include a high frequency component and/or a low frequency component. If present, the high frequency component is provided at about 13.56 MHz. The high frequency component may be provided at a power of about 100 to 750 Watts per 300 mm wafer or between about 100 and 500 Watts per 300 mm wafer. If present, the low frequency component may be provided at a frequency of between about 100 and 1000 kHz or between about 370 and 430 kHz. If present, the low frequency component may be provided a power of between about 0 and 300 Watts for a 300 mm wafer or between about 0 and 100 Watts per 300 mm wafer or between about 0 and 75 Watts per 300 mm wafer.

The silicon nitride films formed as disclosed herein typically possess various characteristics that make them suitable for certain applications in the semiconductor device industry. For example, the films are typically no thicker than about 1000 nanometers. In certain embodiments, the films typically have a thickness of between about 10 and 100 nanometers or between about 30 and 50 nanometers. Additionally, the films are relatively smooth. For example, an arithmetically averaged film roughness (Ra), as measured by atomic force microscopy, is at most about 6.0 Ångstroms for a 1000 Ångstrom thick layer or at most about 4.5 Ångstroms for a 1000 Ångstrom thick layer.

The composition of the silicon nitride deposited film includes silicon, nitrogen, and boron. The film may contain between about 0 and 15 atomic percent boron or between about 0 and 5 atomic percent boron. The film may contain between about 30 and 50 atomic percent silicon. The film may contain between about 25 and 50 atomic percent nitrogen. In certain embodiments, the film contains hydrogen as well as silicon, nitrogen, and boron. If present, hydrogen may constitute a relatively low fraction of the film material, e.g., less than about 18 atomic percent or less than about 15 atomic percent.

The film as-deposited will have an internal stress. As described below, this internal stress can be indicated by the amount of bow in a wafer having the film deposited thereon. Of course, the internal stress can also be represented by the numerical value of tensile or compressive stress in megapascal (MPa). In certain embodiments, the boron-containing silicon nitride films disclosed herein have a tensile internal stress. In certain embodiments, that internal stress is between about 400 and 600 MPa.

Three separate measures of in internal stress were employed in the experimental section below. One of these is a bow shift ratio, which is a comparison of the bow shift in the film under consideration to the bow shift in a silicon nitride film produced by the baseline process. For the bow shift measurement described herein the films all had an as-deposited thickness of 1,000 Å. Deposition of silicon nitride films typically produces some curvature, or bow, in the wafer on which it is deposited. The bow is measured as the z-direction difference between the center and perimeter of the wafer. After annealing, this bow typically shifts to some degree (to produce a wafer with greater or lesser curvature than observed after the initial silicon nitride deposition). The change in bow after annealing is the bow shift, and it is typically reported in units of micrometers. The bow shift of a new silicon nitride film is measured and compared to the bow shift of an equal thickness of silicon nitride using the baseline process. The ratio of these two bow shifts may be used to characterize the films.

Another measure of internal stress of the deposited films involves comparing the stress of the deposited films to a “neutral” internal stress of a true stoichiometric silicon nitride film. This measure is relevant because it is assumed that after a certain amount of thermal processing, the as-deposited silicon nitride film transitions to a true stoichiometric silicon nitride film. This can be observed by heating non-stoichiometric unit layer silicon nitride films for long periods of time. Ultimately, a particular minimum internal stress will be attained, presumably corresponding to the stress associated with the stoichiometric silicon nitride. For silicon nitride the neutral stress has been determined to be approximately 700 MPa tensile.

Yet another parameter related to internal stress in silicon nitride films is the “tunability” of stress with respect to one or more process variables. Some silicon nitride and silicon boronitride films produced in accordance with the disclosed processes can have their stress adjusted to between approximately 1000 MPa tensile and approximately 1000 MPa compressive. The independent variables that drive this tunability are most notably the low frequency RF power, the ammonia concentration in the process gas, and the pressure in the PECVD reactor. Certain experiments presented in the Experimental section show that the internal stress is very sensitive to changes in the low-frequency RF power.

The tunability of the internal stress can be important in certain applications making use of silicon nitride and other materials in stacks, particularly those applications where the electrical properties of the other material must be tightly controlled. In certain embodiments, the internal stress of sacrificial silicon nitride layers may be tuned to offset bowing introduced by other layers which cannot have their internal stresses tuned in the same manner. For example, for certain vertical memory applications, where alternating silicon nitride and silicon oxide layers are deposited, silicon oxide layers are not sacrificial and in fact must have highly specific electrical properties, which greatly constrains the process window for depositing them. Within this tight process window, there is little leeway to adjust parameters to modify the internal stress of the as-deposited silicon oxide layer. Therefore, it is left to the silicon nitride layers to offset any significant bowing introduced by the silicon oxide layers. This can be a significant role for the silicon nitride layers, as the vertical stacks in memory applications typically have many layers and the cumulative effect of the internal stress produced by each of the silicon oxide layers can be very great.

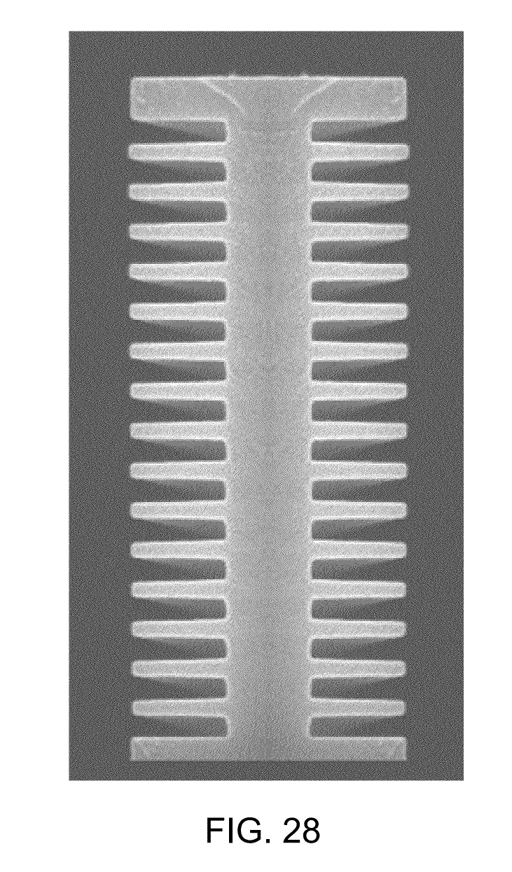

One application of particular interest for using silicon nitride films produced as described herein is in vertical memory stacks. These stacks may employ alternating layers of silicon oxide and silicon nitride. After deposition, the stack is etched to form columns and then the columns are subsequently wet etched to partially or fully remove the sacrificial silicon nitride while substantially preserving the silicon oxide. This produces a “fishbone” structure such as that shown in FIG. 28. In vertical memory applications, the cavities produced by etching the silicon nitride layers may be filled with tungsten to form part of a capacitor.

In the examples presented in the experimental section below, various single layer silicon nitride films (sometimes referred to as “unit layer” films) were produced and then characterized in terms of their chemical composition (Fourier Transform Infrared Spectroscopy (FTIR) spectra), wet-etch rate ratio, internal stress, and other characteristics. Regarding the wet-etch ratio, this was typically measured as a ratio of the wet etch rate of the unit layer silicon nitride film to the wet-etch rate of a thermal oxide film grown at a temperature of 1100° C. Thermal oxide growth on silicon wafers can be achieved using a tube furnace with either wet or dry oxygen as the oxidizing gas. The wet etchant employed was aqueous hydrofluoric acid provided in a volume ratio of 100 units of water to 1 unit standard 50% hydrofluoric acid. In certain embodiments, the ratio of the wet-etch rate of the silicon nitride film relative to the wet etch rate of thermal silicon dioxide in dilute HF is about 0.7 or lower. In some implementations, the wet etch ratio of the silicon nitride to thermal silicon dioxide in dilute HF is between about 0.25 and 0.45. Thermal silicon dioxide is formed by exposing the flat surface of an elemental silicon substrate to oxygen and/or water vapor at a temperature of between about 800 to 1200° C. In some cases, the wet etch rate of silicon nitride in dilute HF is between below about 25 Ångstroms/min. In certain embodiments, the wet etch rate of silicon nitride in dilute HF is between about 10 and 20 Ångstroms/minute or between about 8 and 16 Ångstroms/minute. When using hot phosphoric acid as an etchant, silicon nitride etches faster than thermal silicon dioxide. In some embodiments, silicon nitride formed as described herein etches in hot phosphoric acid at a rate of between about 50 and 200 Ångstroms/minute or between about 100 and 200 Ångstroms/minute. When using hot phosphoric acid, the wet etch ratio between silicon nitride and silicon dioxide is between about 20:1 and 300:1, or between about 30:1 and 200:1, or between about 30:1 and 100:1.

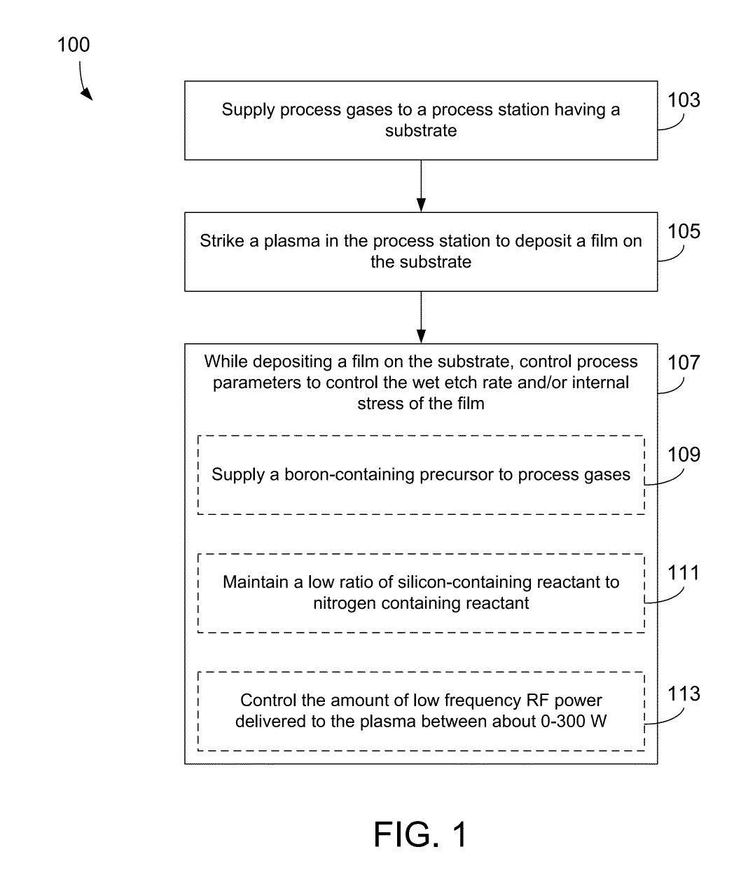

FIG. 1 provides a flowchart of one method 100 of producing a unit layer of silicon nitride in accordance with the embodiments herein. At block 103, process gases are supplied to a process station having a substrate. These process gases will include at least a silicon-containing precursor and a nitrogen-containing precursor. At block 105, a plasma is struck in the process station to deposit a silicon nitride film on the substrate. At block 107, while the silicon nitride film is being deposited on a substrate, one or more process parameters are controlled in order to control the wet etch rate and/or internal stress of the film. For example, a boron-containing precursor may be supplied to the process gases, as shown in block 109. Further, a low ratio of silicon-containing reactant to nitrogen-containing reactant may be maintained, as shown in block 111. In certain embodiments, a “low ratio” of the silicon- to nitrogen-containing reactants means a volumetric ratio below about 0.2. However, in many embodiments the ratio is much lower, for example, a ratio of about 0.02 or below, or 0.013 or below. Another parameter that may be controlled is the low frequency RF power, which may be controlled between about 0-300 Watts per 300 mm wafer, as shown in block 113. These parameters may be varied in order to produce a silicon nitride film with a desired wet etch rate and internal stress.

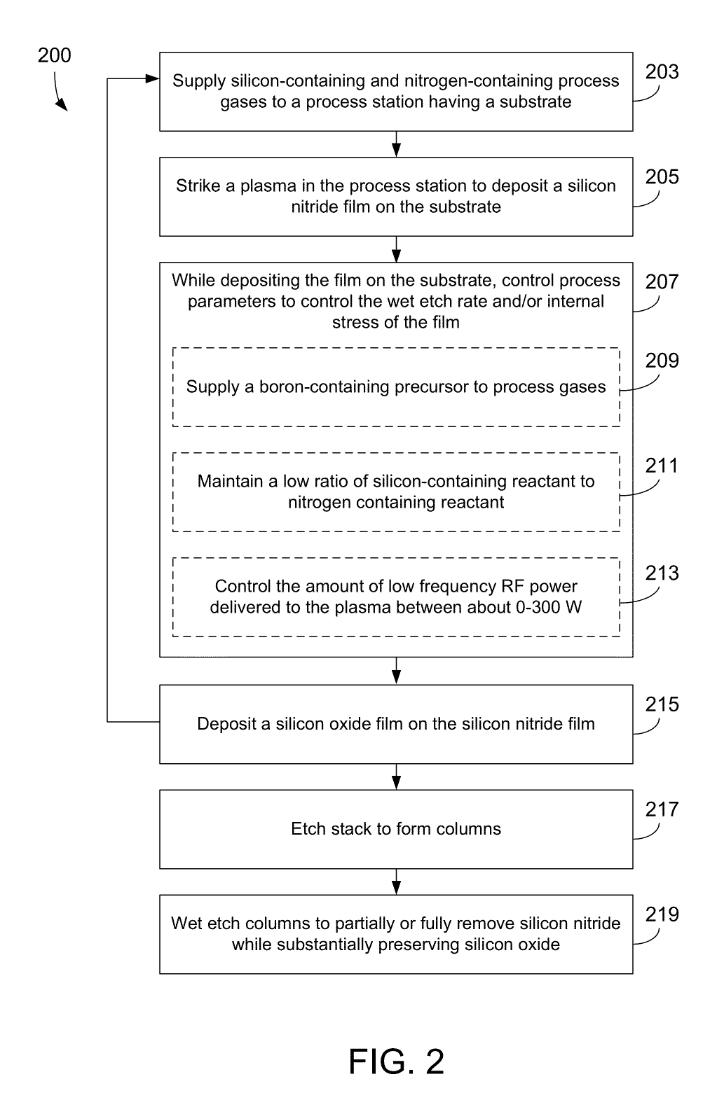

FIG. 2 provides a flow chart showing a method 200 of forming an etched silicon oxide-silicon nitride stack in accordance with the embodiments herein. As illustrated by a block 203, silicon-containing and nitrogen-containing process gases are supplied to a process station having a substrate. At block 205, a plasma is struck in the process station to deposit a silicon nitride film on the substrate. At block 207, while depositing the film, one or more process parameters are controlled in order to control the wet etch rate and/or internal stress of the film. For example, a boron-containing precursor may be supplied to the process gases, as shown in block 209. Also, a low ratio of silicon-containing reactant to nitrogen-containing reactant may be maintained, as shown in block 211. Further, the low frequency RF power may be controlled between about 0-300 Watts per 300 mm wafer, as shown in block 213. These parameters may be varied in order to produce a silicon nitride film with a desired wet etch rate and internal stress. Next, at block 215 a silicon oxide film is deposited on the silicon nitride film. The operations in blocks 203-215 are repeated to form a stack with alternating layers of silicon nitride and silicon oxide. At block 217 the stack is etched to form columns, and at block 219 the columns are wet etched to partially or fully remove the silicon nitride material while substantially preserving the silicon oxide material. This process 200 results in an etched column having cavities into which material may later be deposited or otherwise formed. For example, in certain cases the cavities are filled with capacitor material such as tungsten. By controlling the process parameters in block 207, the resulting stack can achieve a particular desired overall internal stress level. Further, by controlling the process parameters in block 207, a stack may be formed in which the different silicon nitride layers have different wet etch rates. This type of process would result in an etched column with cavities having depths that may be tuned independently of the cavity depths in other layers.

### Apparatus

The methods described herein may be performed by any suitable apparatus. A suitable apparatus includes hardware for accomplishing the process operations and a system controller having instructions for controlling process operations in accordance with the present invention. For example, in some embodiments, the hardware may include one or more process stations included in a process tool.

The system controller will typically include one or more memory devices and one or more processors configured to execute instructions for controlling process operations so that the apparatus will perform a method in accordance with the present disclosure. For example, in some embodiments, the system controller may operate various valves, temperature controllers, plasma controllers, and pressure controllers to adjust process conditions within the apparatus. In some embodiments, machine-readable media containing instructions for controlling process operations in accordance with the present disclosure may be coupled to the system controller.

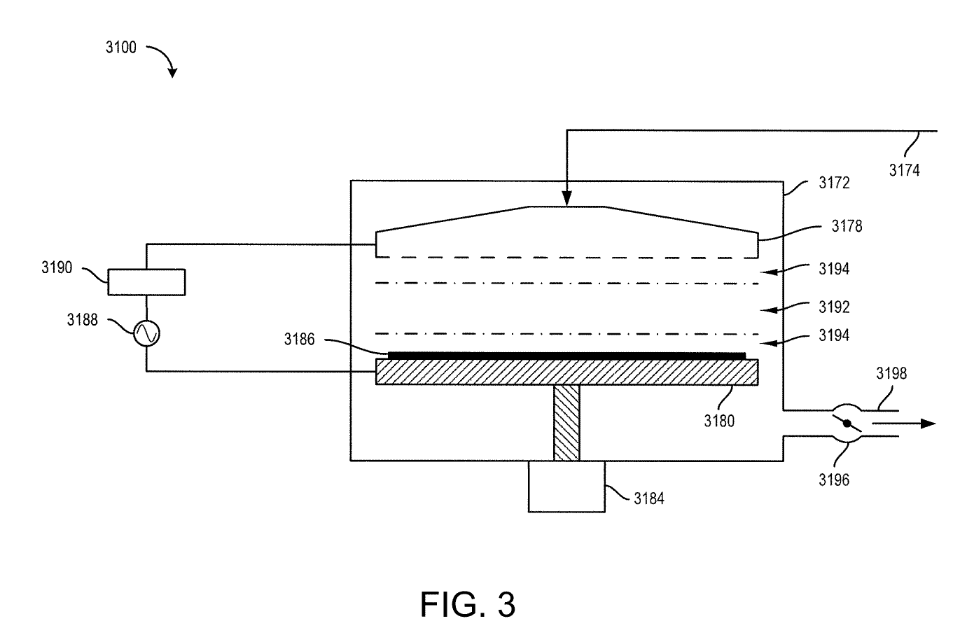

For example, FIG. 3 schematically shows an example embodiment of a process station 3100. For simplicity, process station 3100 is depicted as a standalone process station having a process chamber body 3172 for maintaining a low-pressure environment. However, it will be appreciated that a plurality of process stations 3100 may be included in a common low-pressure process tool environment. Process station 3100 includes a process gas delivery line 3174 for providing process gases, such as inert gases, precursors, reactants, and treatment reactants, for delivery to process station 3100. In the example shown in FIG. 3, a showerhead 3178 is included to distribute process gases within process station 3100. Substrate 3186 is located beneath showerhead 3178, and is shown resting on a holder 3180 supported by a pedestal 3182. In some embodiments, pedestal 3182 may be configured to rotate about a vertical axis. Additionally or alternatively, pedestal 3182 may be configured to translate horizontally and/or vertically.

In some embodiments, showerhead 3178 may be a dual-plenum or multi-plenum showerhead having a plurality of sets of gas distribution holes. For example, a first set of gas distribution holes may receive gas from a first process gas delivery line and a second set of gas distribution holes may receive gas from a second process gas delivery line, etc. Such physical isolation of process gases may provide an approach to reducing the amount of small particles generated from reaction of incompatible process gases in process gas delivery plumbing upstream of showerhead 3178.

Showerhead 3178 and holder 3180 electrically communicate with RF power supply 3188 and matching network 3190 for powering a plasma 3192. Plasma 3192 may be contained by a plasma sheath 3194 located adjacent to showerhead 3178 and holder 3180. While FIG. 3 depicts a capacitively-coupled plasma, plasma 3192 may be generated by any suitable plasma source. In one non-limiting example, plasma 3192 may include a parallel plate plasma source.

In the embodiment shown in FIG. 3, RF power supply 3188 may provide RF power of any suitable frequency. In some embodiments, RF power supply 3188 may be configured to control high- and low-frequency RF power sources independently of one another. Example low-frequency RF powers may include, but are not limited to, frequencies between 200 kHz and 2000 kHz. Example high frequency RF powers may include, but are not limited to, frequencies between 13.56 MHz and 80 MHz. Likewise, RF power supply 3188 and matching network 3190 may be operated at any suitable power to form plasma 3192. Examples of suitable powers include, but are not limited to, powers between 250 W and 5000 W for a high-frequency plasma (assuming a four station reaction chamber) and powers between 0 W and 2500 W (assuming a four station reaction chamber) for a low-frequency plasma for a four-station multi-process tool including four 15-inch showerheads. RF power supply 3188 may be operated at any suitable duty cycle. Examples of suitable duty cycles include, but are not limited to, duty cycles of between 5% and 90%.

In some embodiments, holder 3180 may be temperature controlled via heater 3184. Further, in some embodiments, pressure control for process station 3100 may be provided by butterfly valve 3196 or by any other suitable pressure control device. As shown in FIG. 3, butterfly valve 3196 throttles a vacuum provided by a vacuum pump (not shown) fluidly coupled to process station exhaust line 3198. However, in some embodiments, pressure control of process station 3100 may also be adjusted by varying a flow rate of one or more gases introduced to process station 3100.

It will be appreciated that control of one or more process parameters may be provided locally (e.g., RF power may be controlled by a plasma controller communicating with RF power supply 3188, process station pressure may be controlled by a valve controller communicating with butterfly valve 3196 or with gas metering valves or flow controllers included coupled with process gas delivery line 3174, etc.) or under partial or total control provided by a system controller (described in more detail below) communicating with process station 3100 without departing from the scope of the present disclosure.

As described above, one or more process stations may be included in a multi-station processing tool. In some embodiments of a multi-station process tool, control and/or supply of various process inputs (e.g., process gases, plasma power, heater power, etc.) may be distributed from shared sources to a plurality of process stations included in the process tool. For example, in some embodiments, a shared plasma generator may supply plasma power to two or more process stations. In another example, a shared gas distribution manifold may supply process gases to two or more process stations.

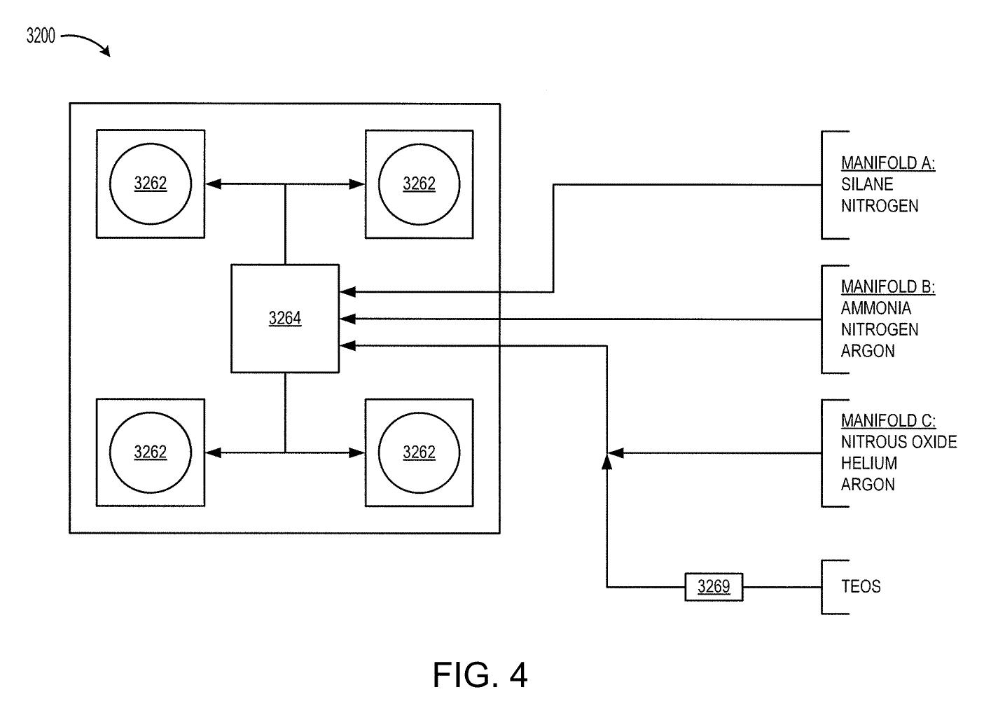

For example, FIG. 4 schematically shows an example process tool 3200, which includes a plurality of processing stations 3262 in a low-pressure environment. Each processing station 3262 is configured to deposit an ultra-smooth PECVD silane-based silicon dioxide and a silane-based silicon nitride. Each processing station 3262 is supplied by a common mixing vessel 3264 for blending and/or conditioning process gases prior to delivery to each processing station 3262.

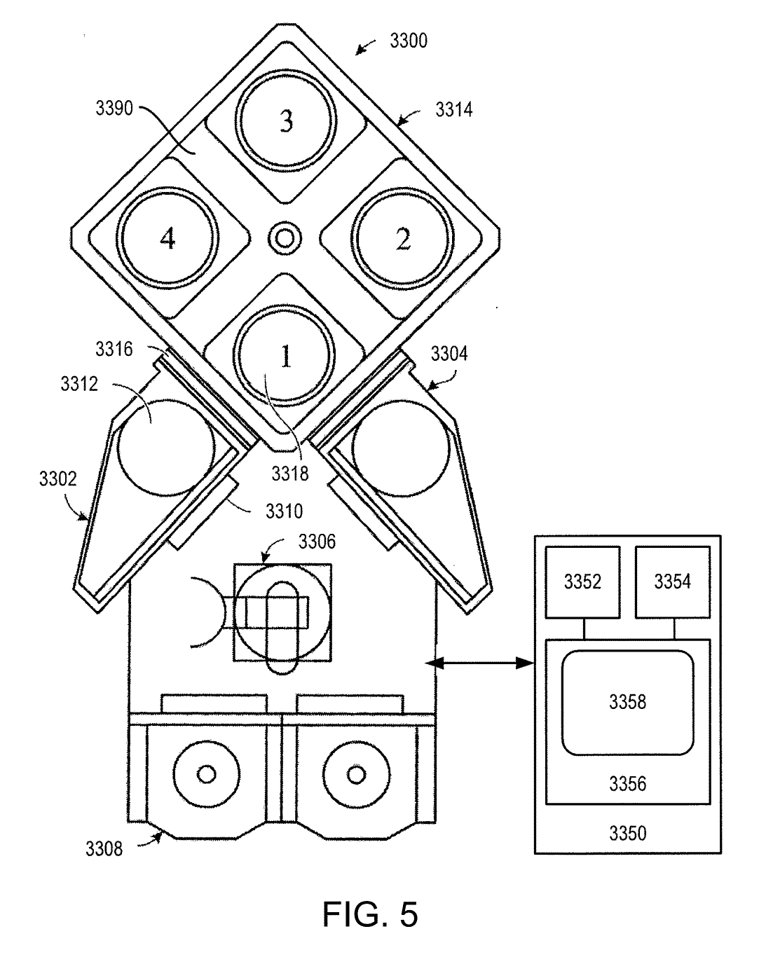

FIG. 5 shows a schematic view of an embodiment of another multi-station processing tool 3300 with an inbound load lock 3302 and an outbound load lock 3304. A robot 3306, at atmospheric pressure, is configured to move substrates from a cassette loaded through a pod 3308 into inbound load lock 3302 via an atmospheric port 3310. Inbound load lock 3302 is coupled to a vacuum source (not shown) so that, when atmospheric port 3310 is closed, inbound load lock 3302 may be pumped down. Inbound load lock 3302 also includes a chamber transport port 3316 interfaced with processing chamber 3314. Thus, when chamber transport 3316 is opened, another robot (not shown) may move the substrate from inbound load lock 3302 to a pedestal of a first process station for processing.

In some embodiments, inbound load lock 3302 may be connected to a remote plasma source (not shown) configured to supply a plasma to load lock. This may provide remote plasma treatments to a substrate positioned in inbound load lock 3302. Additionally or alternatively, in some embodiments, inbound load lock 3302 may include a heater (not shown) configured to heat a substrate. This may remove moisture and gases adsorbed on a substrate positioned in inbound load lock 3302. While the embodiment depicted in FIG. 5 includes load locks, it will be appreciated that, in some embodiments, direct entry of a substrate into a process station may be provided.

The depicted processing chamber 3314 comprises four process stations, numbered from 1 to 4 in the embodiment shown in FIG. 5. In some embodiments, processing chamber 3314 may be configured to maintain a low pressure environment so that substrates may be transferred among the process stations without experiencing a vacuum break and/or air exposure. Each process station depicted in FIG. 5 includes a process station substrate holder (shown at 3318 for station 1) and process gas delivery line inlets. In some embodiments, one or more process station substrate holders 3318 may be heated.

In some embodiments, each process station may have different or multiple purposes. For example, a process station may be switchable between a tunable wet etch ratio and internal stress process mode and a conventional PECVD or CVD mode. Additionally or alternatively, in some embodiments, processing chamber 3314 may include one or more matched pairs of tunable wet etch ratio/stress and conventional PECVD stations (e.g., a pair including a tunable wet etch ratio/stress PECVD SiN station and a conventional PECVD SiO₂ station). In another example, a process station may be switchable between two or more film types, so that stacks of different film types may be deposited in the same process chamber.

While the depicted processing chamber 3314 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 5 also depicts an embodiment of a substrate handling system 3390 for transferring substrates within processing chamber 3314. In some embodiments, substrate handling system 3390 may be configured to transfer substrates between various process stations and/or between a process station and a load lock. It will be appreciated that any suitable substrate handling system may be employed. Non-limiting examples include substrate carousels and substrate handling robots.

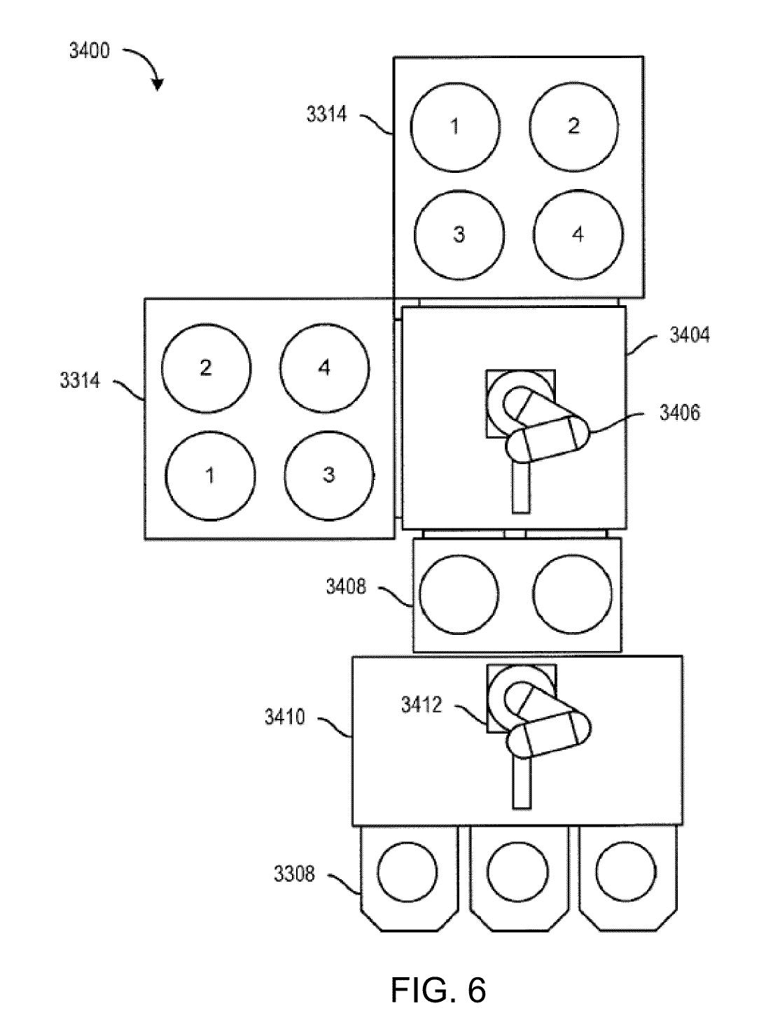

It will be appreciated that, in some embodiments, a low-pressure transfer chamber may be included in a multistation processing tool to facilitate transfer between a plurality of processing chambers. For example, FIG. 6 schematically shows another embodiment of a multi-station processing tool 3400. In the embodiment shown in FIG. 6, multi-station processing tool 3400 includes a plurality of processing chambers 3314 including a plurality of process stations (numbered 1 through 4). Processing chambers 3314 are interfaced with a low-pressure transport chamber 3404 including a robot 3406 configured to transport substrates between processing chambers 3314 and load lock 3408. An atmospheric substrate transfer module 3410, including an atmospheric robot 3412, is configured to facilitate transfer of substrates between load lock 3408 and pod 3308.

Turning back to FIG. 5, multi-station processing tool 3300 also includes an embodiment of a system controller 3350 employed to control process conditions and hardware states of processing tool 3300. For example, in some embodiments, system controller 3350 may control one or more process parameters during a PECVD film deposition phase to achieve a desired wet etch rate or internal stress of the deposited film. While not shown in FIG. 6, it will be appreciated that the embodiment of multi-station processing tool 3400 may include a suitable system controller like the embodiment of system controller 3350 shown in FIG. 5.

System controller 3350 may include one or more memory devices 3356, one or more mass storage devices 3354, and one or more processors 3352. Processor 3352 may include a CPU or computer, analog and/or digital input/output connections, stepper motor controller boards, etc.

In some embodiments, system controller 3350 controls all of the activities of processing tool 3300. In some embodiments, system controller 3350 executes machine-readable system control software 3358 stored in mass storage device 3354, loaded into memory device 3356, and executed on processor 3352. Alternatively, the control logic may be hard coded in the controller. Applications Specific Integrated Circuits, Programmable Logic Devices (e.g., FPGAs) and the like may be used for these purposes. In the following discussion, wherever “software” or “code” is used, functionally comparable hard coded logic may be used in its place.

System control software 3358 may include instructions for controlling the timing, mixture of gases, chamber and/or station pressure, chamber and/or station temperature, substrate temperature, target power levels, RF power levels, substrate pedestal, chuck and/or susceptor position, and other parameters of a particular process performed by processing tool 3300. System control software 3358 may be configured in any suitable way. For example, various process tool component subroutines or control objects may be written to control operation of the process tool components for performing various process tool processes. System control software 3358 may be coded in any suitable computer readable programming language.

In some embodiments, system control software 3358 may include input/output control (IOC) sequencing instructions for controlling the various parameters described above. For example, each phase of a tunable wet etch rate/stress process may include one or more instructions for execution by system controller 3350. The instructions for setting process conditions for a tunable PECVD process phase may be included in a corresponding tunable recipe phase. In some embodiments, the tunable PECVD recipe phases may be sequentially arranged, so that all instructions for—a tunable PECVD process phase are executed concurrently with that process phase.

Other computer software and/or programs stored on mass storage device 3354 and/or memory device 3356 associated with system controller 3350 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto process station substrate holder 3318 and to control the spacing between the substrate and other parts of processing tool 3300.

A process gas control program may include code for controlling gas composition and flow rates and optionally for flowing gas into one or more process stations prior to deposition in order to stabilize the pressure in the process station. For example, the process gas control program may include code for achieving a desired wet etch rate and/or internal stress by supplying a particular amount of a boron-containing precursor such as diborane. The amount of diborane flowed is determined by the controller based on the desired wet etch rate and/or internal stress. As another example, the process gas control program may include code for achieving a desired wet etch rate and/or internal stress by supplying a particular ratio of silane-containing precursor to nitrogen-containing precursor. The ratio of these precursors is controlled by the controller to achieve the desired film property. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations. In one example, a plasma control program may include code for setting the LF RF power level based on a desired internal stress level.

In some embodiments, there may be a user interface associated with system controller 3350. The user interface may include a display screen, graphical software displays of the apparatus and/or process conditions, and user input devices such as pointing devices, keyboards, touch screens, microphones, etc.

In some embodiments, parameters adjusted by system controller 3350 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 3350 from various process tool sensors. The signals for controlling the process may be output on the analog and digital output connections of processing tool 3300. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 3350 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The various hardware and method embodiments described above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

Lithographic patterning of a film typically comprises some or all of the following steps, each step enabled with a number of possible tools: (1) application of photoresist on a workpiece, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above described processes may be changed.

The electroplating apparatus/methods described hereinabove may be used in conjunction with lithographic patterning tools or processes, for example, for the fabrication or manufacture of semiconductor devices, displays, LEDs, photovoltaic panels and the like. Generally, though not necessarily, such tools/processes will be used or conducted together in a common fabrication facility. Lithographic patterning of a film generally comprises some or all of the following steps, each step enabled with a number of possible tools: (1) application of photoresist on a work piece, i.e., a substrate, using a spin-on or spray-on tool; (2) curing of photoresist using a hot plate or furnace or UV curing tool; (3) exposing the photoresist to visible, UV, or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper.

The subject matter of the present disclosure includes all novel and nonobvious combinations and sub-combinations of the various processes, systems and configurations, and other features, functions, acts, and/or properties disclosed herein, as well as any and all equivalents thereof.

### Experimental

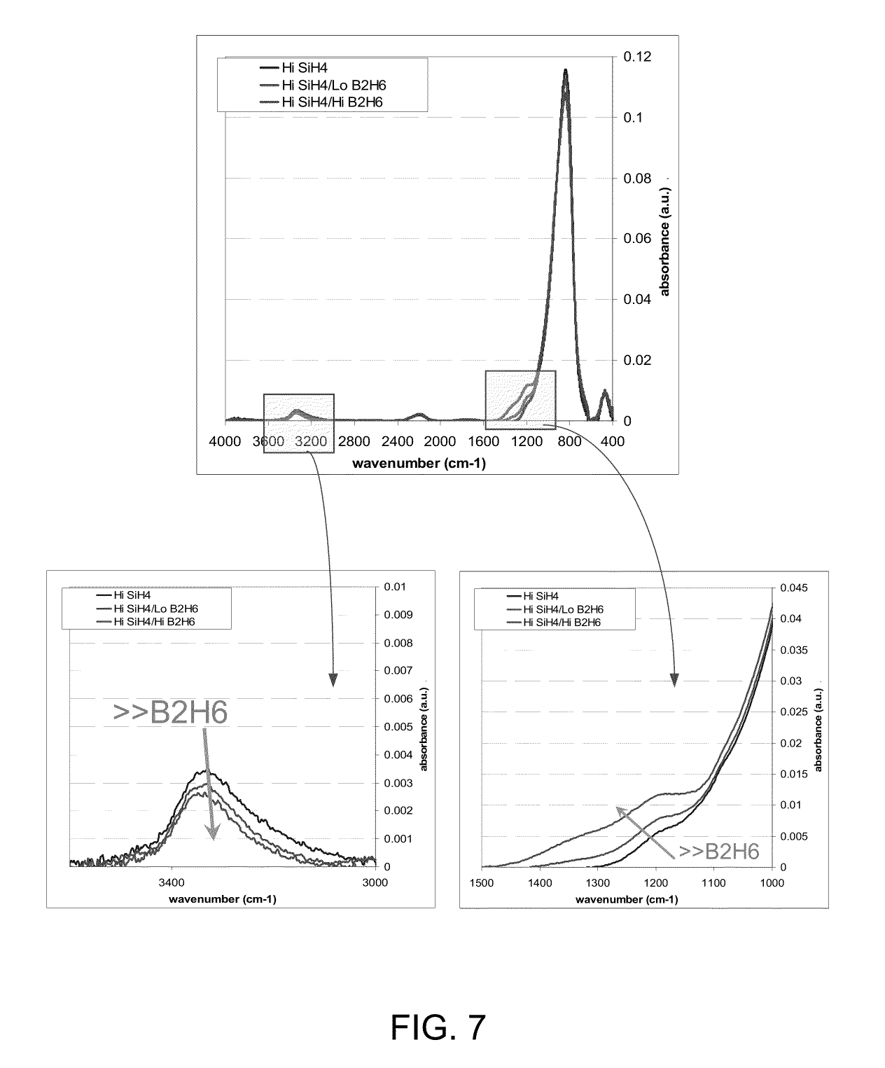

The following description explains certain aspects of FIGS. 7-27. Much of the discussion concerns process parameters and process variations made with respect to a baseline process for depositing silicon nitride films. Specifically, the baseline silicon nitride films have a relatively low quantity of silicon-hydrogen bonding.

Analysis has determined that some samples of the baseline SiN film contain about 13.4 atomic percent hydrogen as determined by RBS/HFS spectroscopy. This same film was found to have a hydrogen concentration of 15.6% when measured by FTIR, using an assumed bond density of 8.9×10²²/cm³. The film was smooth, with average roughness Ra of 5.0 Ångstroms as determined by Atomic Force Microscopy.

The baseline process is a plasma enhanced chemical vapor deposition (PECVD) process that employs silane and ammonia as reactant process gases. Nitrogen is used as a carrier gas. In the baseline process, these process gases are delivered to a four station reactor (e.g., a Vector® Extreme or Vector® Express reactor from Novellus Systems, Inc. of San Jose, Calif.) where they are reacted to produce silicon nitride films on 300 mm wafers. The silane is delivered at a flow rate of about 200 sccm (100% silane), the ammonia is delivered at about 1140 sccm, and the nitrogen at about 9000 sccm. The pressure employed in the process is about 2 Torr. Low-frequency & high-frequency RF power is provided to generate the plasma. It employs a low frequency radio frequency (LF RF) of 400 kHz at a power of about 0 to 150 Watts (about 0-40 W per 300 mm wafer) and a high frequency radio frequency (HF RF) of 13.56 MHz at a power of about 800 Watts (about 200 W per 300 mm wafer).

Turning now to FIGS. 7-27, some terminology will be described.

“Ratio Bow Shift,” “Bow Ratio,” and “Bow Shift Ratio” refer to the ratio of wafer bow shift induced by annealing a silicon nitride layer produced using the improved processes described herein to the bow shift induced by annealing a silicon nitride layer produced by the baseline process. Generally, a suitable result will be observed when the new silicon nitride layer produces a bow shift that is nominally equal to or less than the bow shift exhibited by the silicon nitride produced by the baseline process. However, in certain implementations it may be desirable to achieve a bow shift ratio above 1. As described herein, the internal stress of the silicon nitride layer (one measure of which is the bow shift) may be tuned to offset stress induced by other layers. As such, the target bow shift ratio may be variable based on the particular application.

The terms “LowHSiN” and “LowH (BKM)” refer to silicon nitride produced using the baseline process. It is presumed that the silicon nitride produced by the baseline process has a relatively low content of silicon hydrogen bonding.

The parameter “WER ratio” refers to the wet-etch rate ratio between a thermal oxide film grown at a temperature of 1100° C. and a silicon nitride film under consideration. The etch rate of a film is determined by exposing it to dilute hydrofluoric acid as described above.

The parameter “AFM Ra” is a measure of the average roughness of the surface of the substrate (an arithmetic mean).

The spectra presented in FIG. 7 are FTIR spectra of three different silicon nitride and silicon boronitride films produced using (1) the baseline process, (2) the baseline process with a small amount of diborane introduced, and (3) the baseline process with a higher amount of diborane introduced. The total flow rates of diborane in the low and high diborane cases were 80 and 260 sccm diborane in 95% argon (i.e., 4 sccm diborne in 76 sccm argon and 13 sccm diborane in 247 sccm argon, respectively).

In the plot on the lower right hand side, the baseline process is shown in the lower curve, the low diborane process is represented by the intermediate curve, and the high diborane process is represented by the upper curve. The relative positions of these curves are reversed in the plot on the lower left, i.e. the plot having a peak centered near 3300 reciprocal centimeters. Notably, the FTIR shows that increasing the diborane flow results in two B—N peaks appearing at around 1200 cm⁻¹ and 1380 cm⁻¹. Further, higher diborane flow leads to a lower N—H peak and corresponding area.

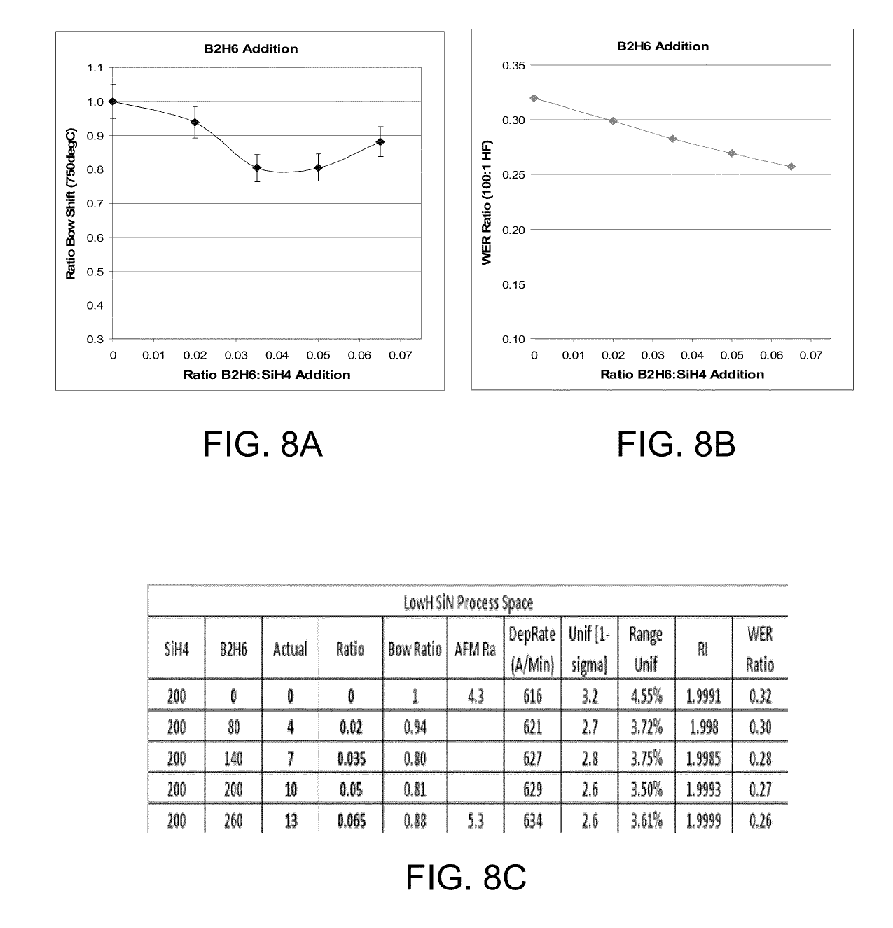

FIG. 8A shows a graph of the bow shift ratio vs. the ratio of diborane to silane for silicon nitride films. FIG. 8B shows a graph of the wet etch rate ratio vs. the ratio of diborane to silane. In FIGS. 8A-B, the x-axis may also be characterized as the amount of diborane flowed because the amount of silane flowed was constant between the samples. The wet etch rate ratio decreases as the flow of diborane increases. FIG. 8C shows a table of the process space for the films characterized in FIGS. 8A-B, which employ varying amounts of diborane in the baseline silicon nitride deposition process. These examples include the two diborane examples characterized by the spectra in FIG. 7. As mentioned, all processing was conducted in a Novellus Systems PECVD reactor having four stations, each for holding a 300 mm wafer. The silane flow rate in each of the examples was 200 sccm. The diborane flow rate varied between 0 and 260 sccm. It should be noted that the diborane is provided in a carrier gas. In the specific examples here, 5% diborane was provided in a carrier of 95% argon. It should be understood that other carrier gases besides argon may be employed. Nitrogen and hydrogen are examples.

The third column in FIG. 8C depicts the actual volumetric flow rate of diborane adjusted to account for the argon carrier; i.e., recognizing that diborane constitutes only 5% of the total volume of the “diborane” gas delivered to the reaction chamber. The column labeled “ratio” refers to the ratio of actual diborane volume to silane volume. The column labeled “AFM Ra” represents the average surface roughness of the deposited film in units of Ångstroms. Note that the films measured for roughness were approximately 1000 Å thick. The deposition rate is provided in Ångstroms per minute. The eighth and ninth columns of the table show the within wafer non-uniformity of the deposited film. The 10th column presents the refractive index of the deposited films. The films were targeted to have an as-deposited stress of about +100 MPa.

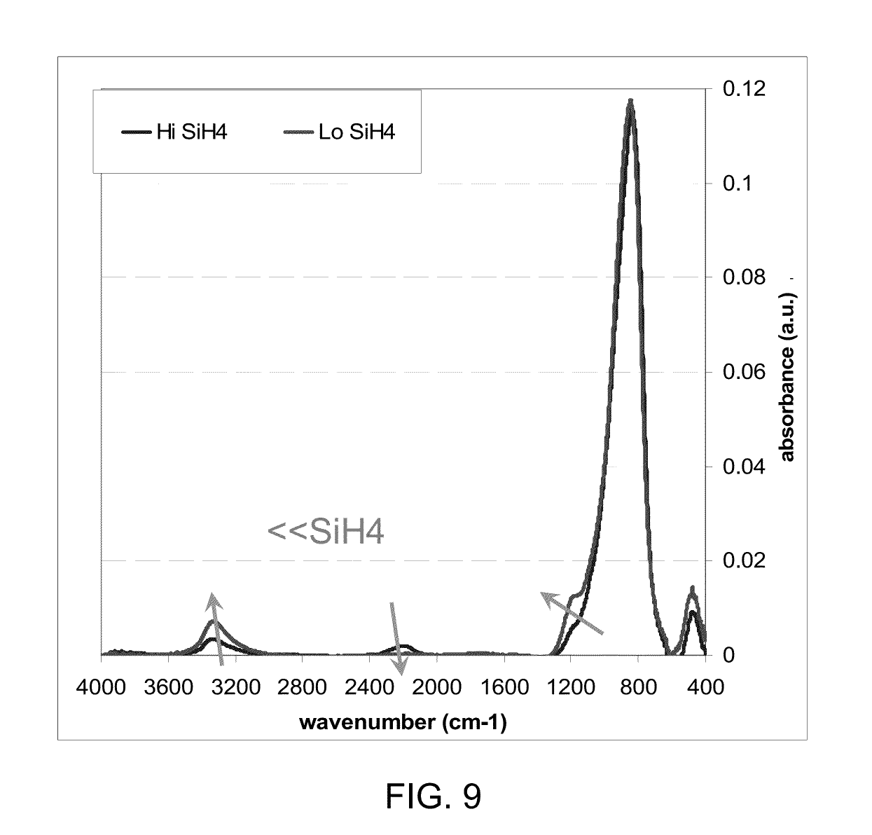

FIGS. 9-12 depict examples employing a variation of the baseline process in which a relatively small amount of silane was used to deposit the film. Specifically, while the baseline process employed 200 sccm of silane, the low silane process employed only 40 sccm of silane. Otherwise, the process conditions were the same as those employed in the baseline process. Further aspects of low silane processing may be understood by reviewing U.S. patent application Ser. No. 12/970,853, filed Dec. 16, 2010 (U.S. Published Patent Application 2011-0236600-A1), which is incorporated herein by reference in its entirety.

In FIG. 9, FTIR spectra are presented for the baseline process and for the low silane process. Of note, the low silane process resulted in the effective removal of a silicon-hydrogen bond peak at approximately 2200 cm⁻¹, as well as higher nitrogen-hydrogen peaks/areas around 1200 cm⁻¹ and 3330 cm⁻¹.

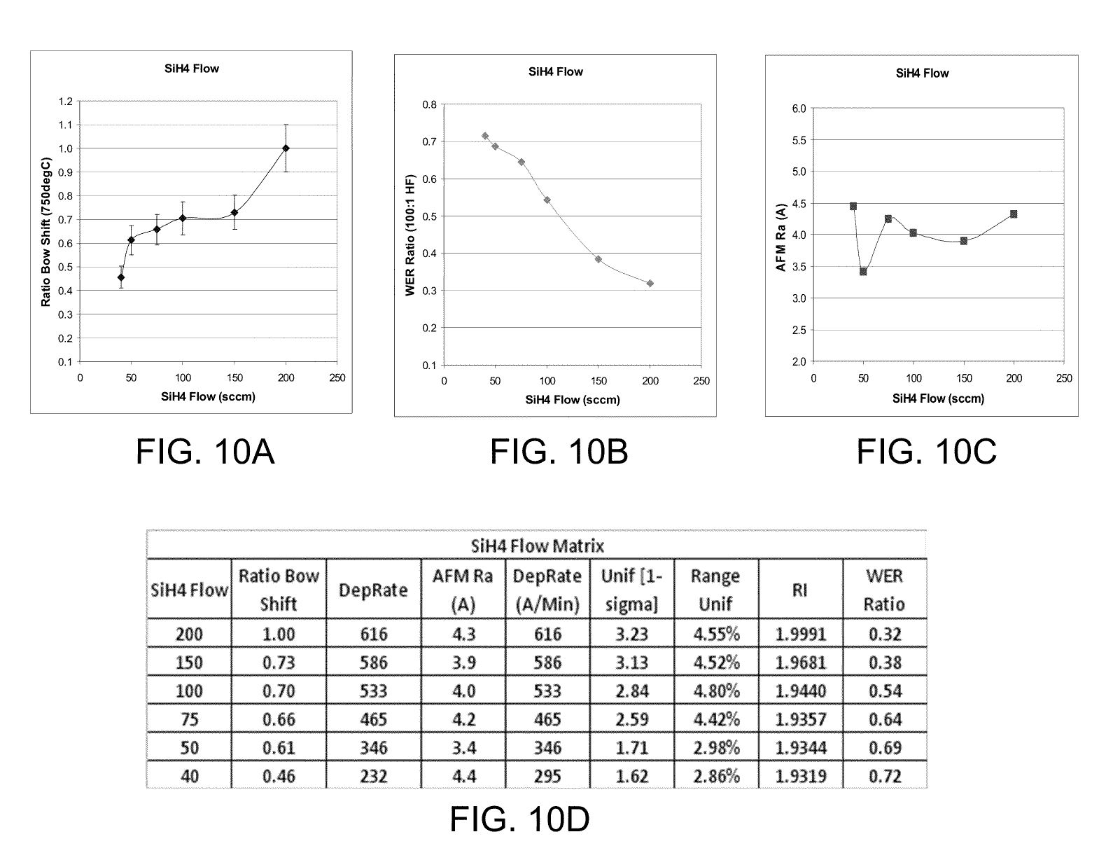

FIGS. 10A-C show how certain film properties (bow shift ratio (10A), wet etch rate ratio (10B), and surface roughness (10C)) vary as a function of the silane flow rate. FIG. 10D shows the reaction parameters and resulting film properties for the films characterized in FIGS. 10A-C. Of particular note, the bow shift ratio and the wet etch rate ratio are very strong functions of the silane flow rate. The reduced internal stress (here a bow shift ratio as low as 0.46), increased wet etch ratio (here as high as about 0.7), and improved within wafer non-uniformity strongly suggest that the low silane process can be used to advantage in some silicon nitride deposition processes.

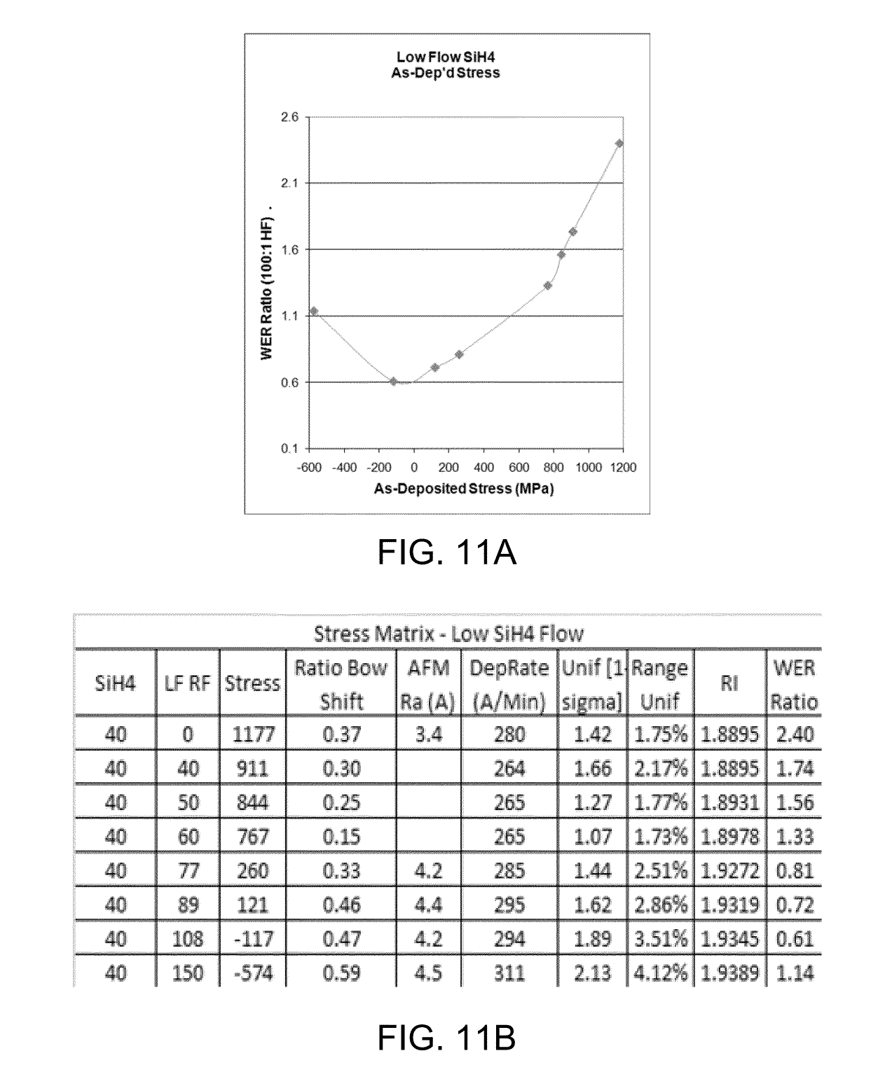

FIG. 11A shows the wet etch rate ratio as a function of the as-deposited stress for films produced according to a low silane process disclosed herein. FIG. 11B shows how low-frequency RF power impacts the internal stress and other film parameters of films produced with a low silane process (in this case 40 sccm silane). The second column of FIG. 11B presents the low-frequency RF power in Watts. The stress, which is shown in the third column, is presented in MPa. It can be seen from these results that the internal stress is a strong function of the low-frequency RF power. The data in FIGS. 11A-B also show that the wet etch ratio is a reasonably strong function of the as-deposited stress.

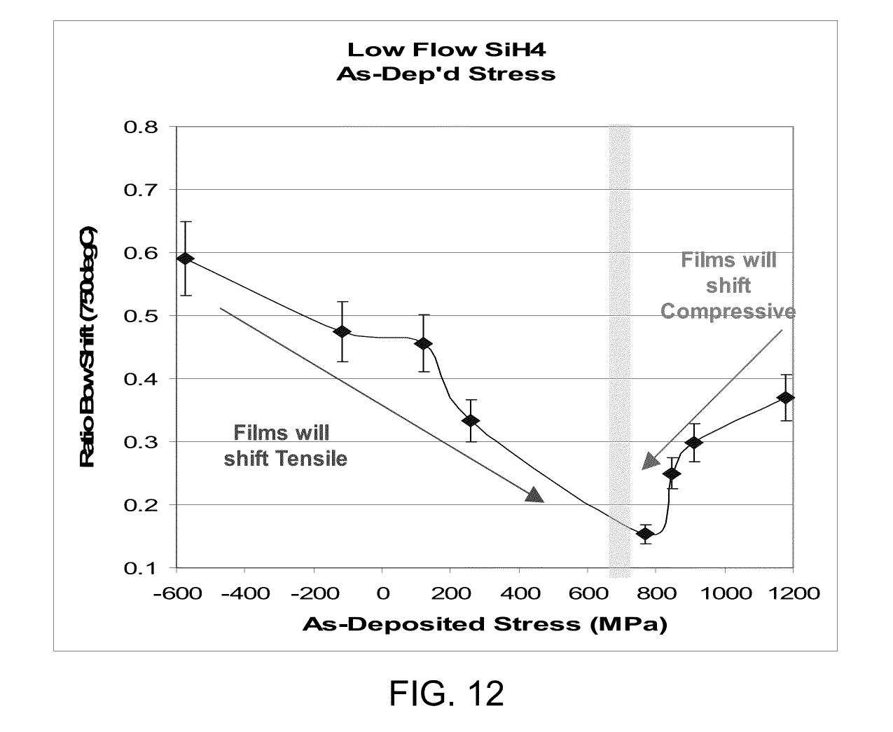

The plot presented in FIG. 12 shows the bow shift ratio as a function of the as-deposited internal stress of the silicon nitride films. Interestingly, a “neutral silicon nitride” region at about 700 MPa tensile has a minimum bow shift ratio. It is believed that the composition of silicon nitride in films with this internal stress is approximately stoichiometric. After deposition, it is believed that non-stoichiometric films gradually move toward stoichiometric compositions due to exposure to thermal energy and possibly other influences encountered during subsequent processing, thereby shifting the internal stress towards about 700 MPa tensile. Therefore, it may be desirable in some embodiments to deposit films at their neutral level of stress to prevent the film from shifting, thereby improving the thermal stability of the deposited film.

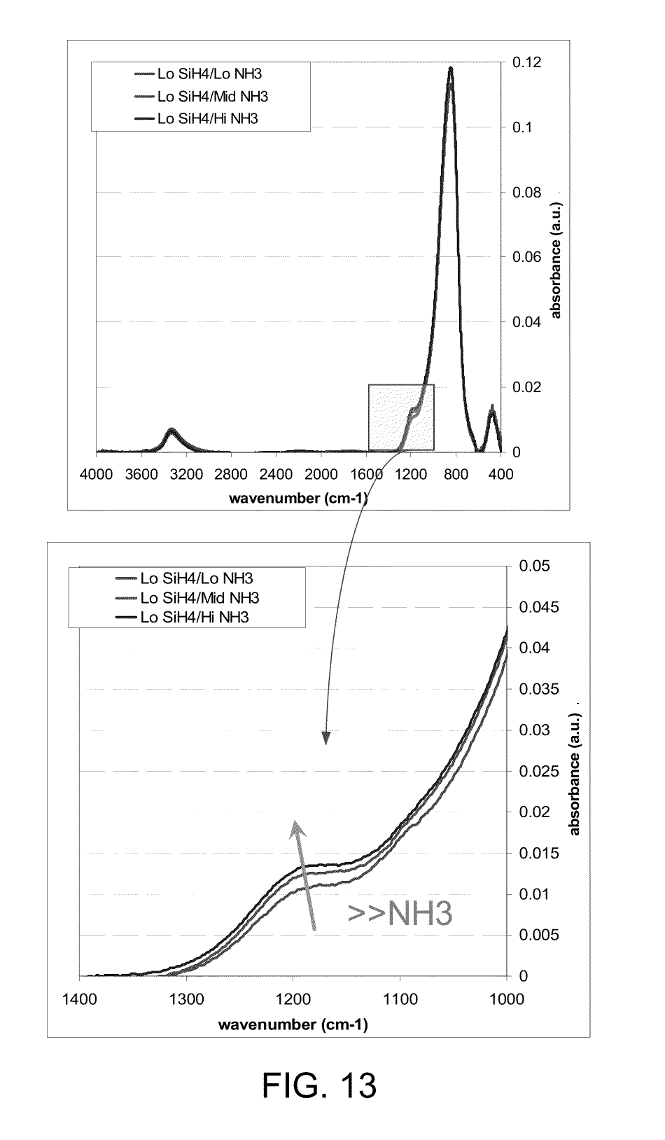

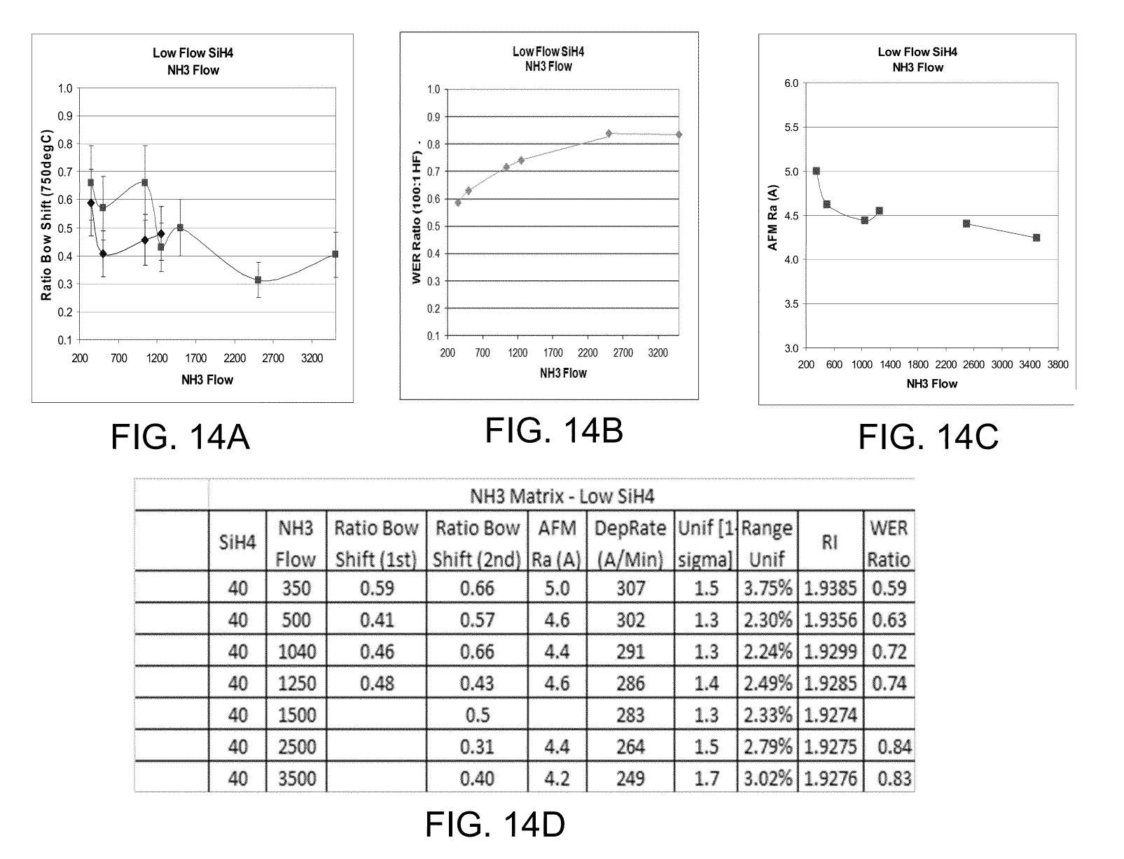

FIGS. 13 and 14A-D illustrate the effect of the ammonia flow rate in the low silane process space described above. FIG. 13 shows the FTIR spectra of silicon nitride films produced according to a low silane process with varying amounts of ammonia. Samples prepared with increased amounts of ammonia flow show an increase in the nitrogen-hydrogen bond peak at around 1200 cm⁻¹. FIGS. 14A-C show how certain film properties (bow shift ratio (14A), wet etch rate ratio (14B), and surface roughness (14C)) vary as a function of the ammonia flow rate. As shown in FIG. 14D, the ammonia flow rate was varied between 350 sccm and 3500 sccm. In all examples, the silane flow rate remained constant at 40 sccm. High amounts of ammonia flow may result in lower bow shift ratios (here as low as 0.31). Of interest, the ammonia flow rate had a strong effect on the wet etch rate of the deposited silicon nitride film. Increasing the ammonia flow rate from 350 sccm to 2500 sccm resulted in a gradual but significant increase in the wet etch ratio of the deposited film (here as high as 0.84). Further, increasing the ammonia flow rate had a generally positive impact on surface roughness of the deposited film.

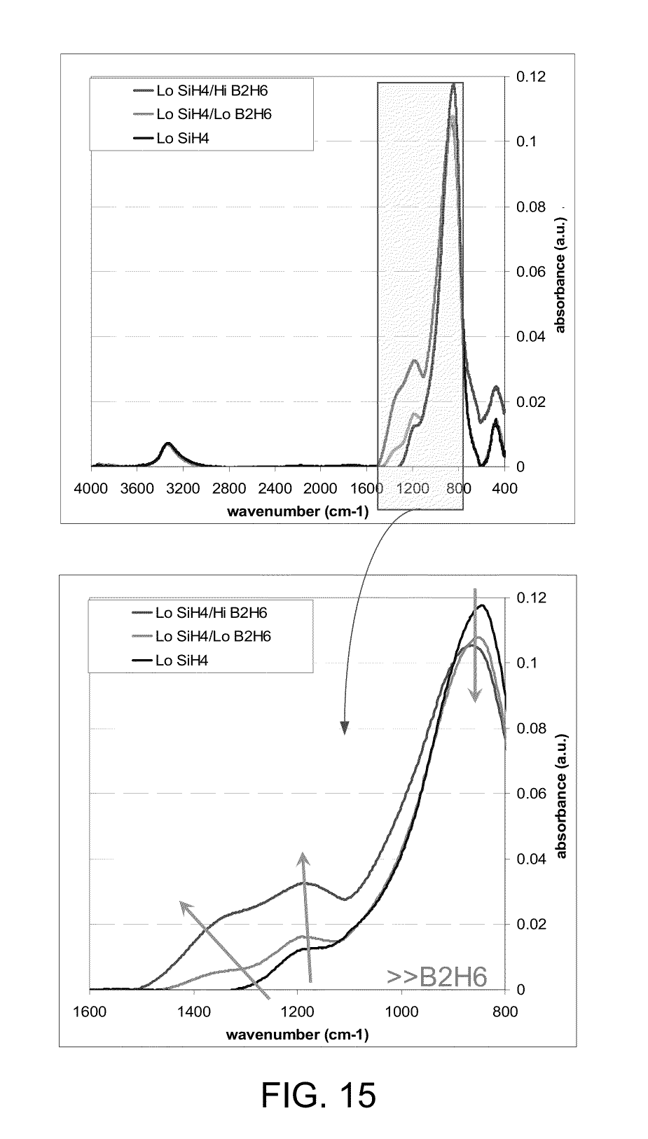

Films deposited using processes employing diborane are characterized in FIGS. 15-17. These processes employ diborane in a low silane process flow. The process conditions for the data shown in FIGS. 15-17 are as follows:

SiH₄=40 sccm

NH₃=1040 sccm

N₂=9000 sccm

Diborane varied as noted in table on Page 11

Pressure=2.4 torr

Temperature 550° C.

HFRF=800 W (200 W per 300 mm wafer)

LFRF=adjusted between 65 and 100 W to tune stress (between 16-25 W per 300 mm wafer)

FIGS. 15-17 depict the impact of the addition of diborane to the process gas in the low silane flow process space. It is believed that the presence of diborane in the process gas produces a film that is qualitatively different than silicon nitride produced by other processes described herein. It is believed that the film is a silicon boronitride.

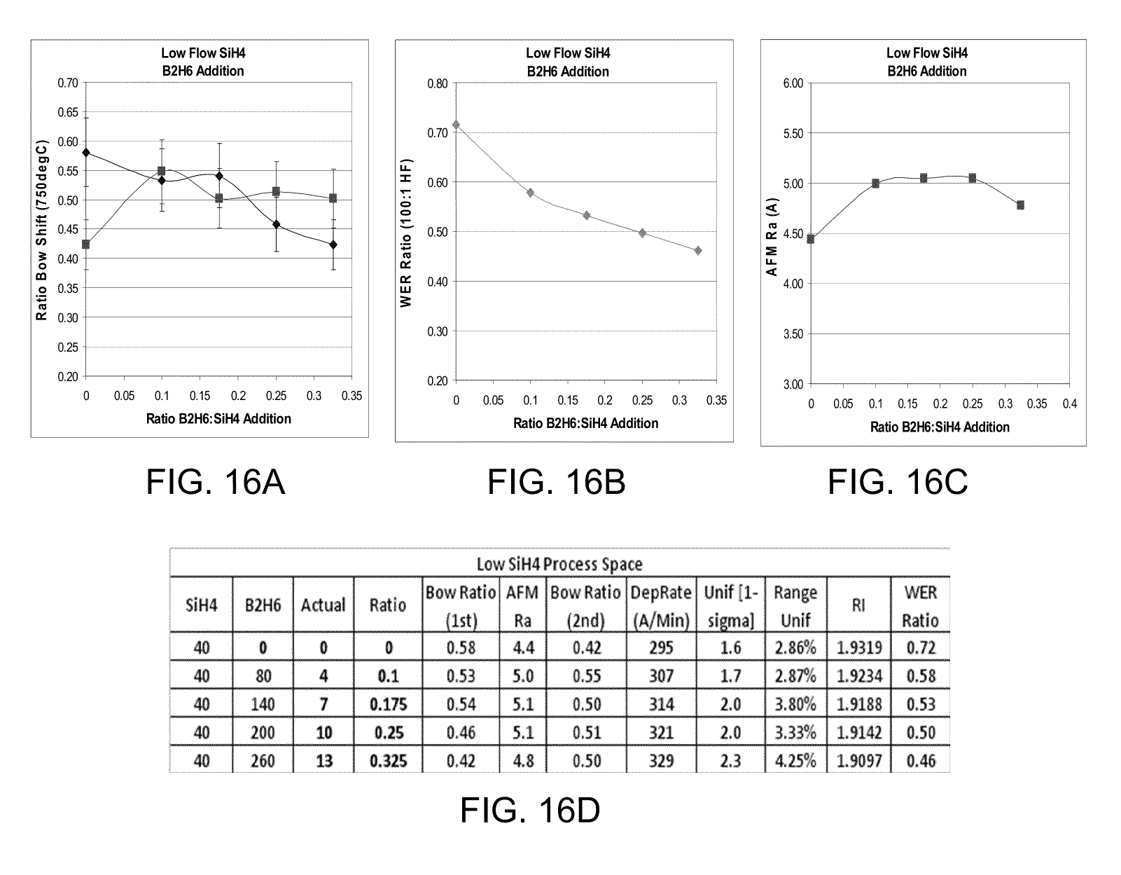

All examples and information provided in FIGS. 15-17 were conducted under process conditions identical to those described previously for the low silane process, except that in some cases diborane was added. In FIG. 15, the “low” diborane process employed 80 sccm of 5% diborane and the “high” diborane process employed 260 sccm of 5% diborane. The actual ratio of diborane to silane is depicted in the fourth column of FIG. 16D. The addition of diborane to the low silane process significantly improves the bow shift ratio as depicted in FIG. 16A (here as low as 0.42). The amount of diborane also strongly influences the wet etch rate with dilute hydrofluoric acid, as shown in FIG. 16B. Increasing the amount of diborane in the process gases leads to additional boron-nitrogen peaks appearing at around 1200 cm⁻¹ and 1380 cm⁻¹, as well as a decrease to the silicon-nitrogen peak around 845 cm⁻¹.

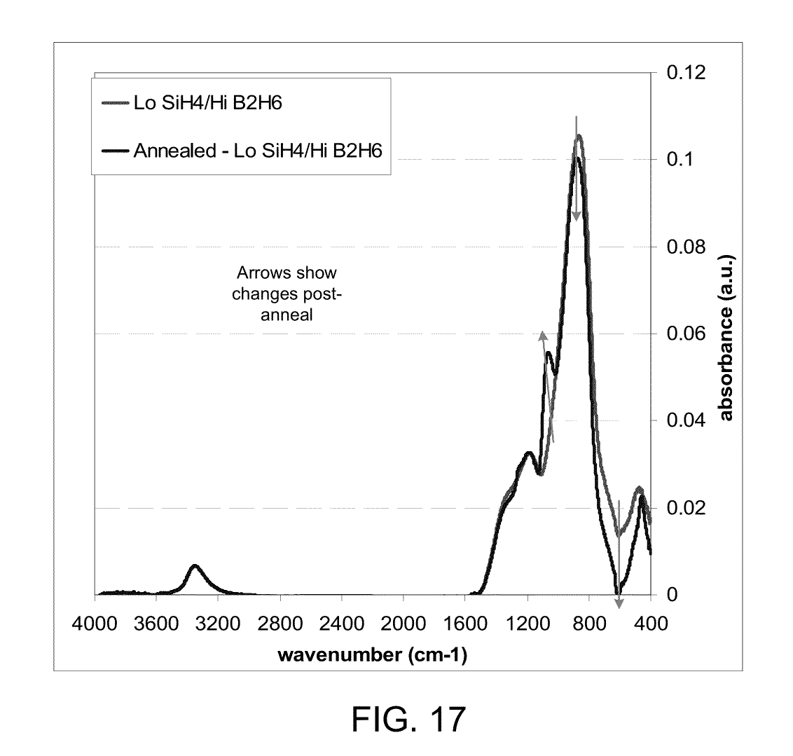

FIG. 17 shows the FTIR spectra for the low silane/high diborane process, both before and after annealing at 750° C. for two hours in an atmospheric furnace. The gray arrows show the changes in the spectra after annealing. Notably, after the sample was annealed, a new peak appeared around 1070 cm⁻¹. It is possible that oxidation may have occurred on the wafer backside during the annealing process. Further, the silicon-nitrogen peak at 845 cm⁻¹ was decreased.

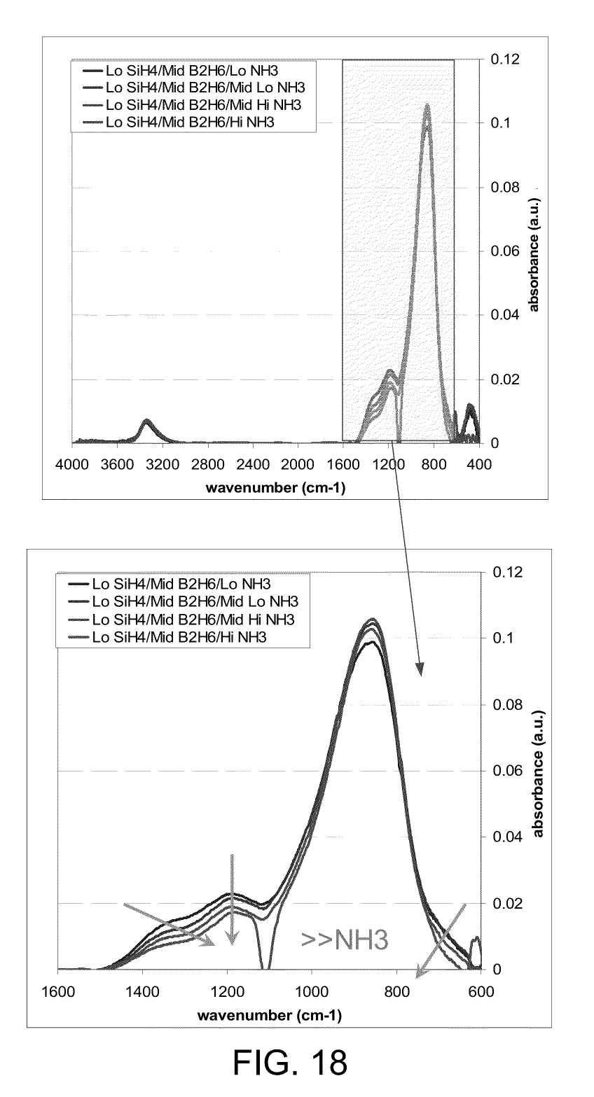

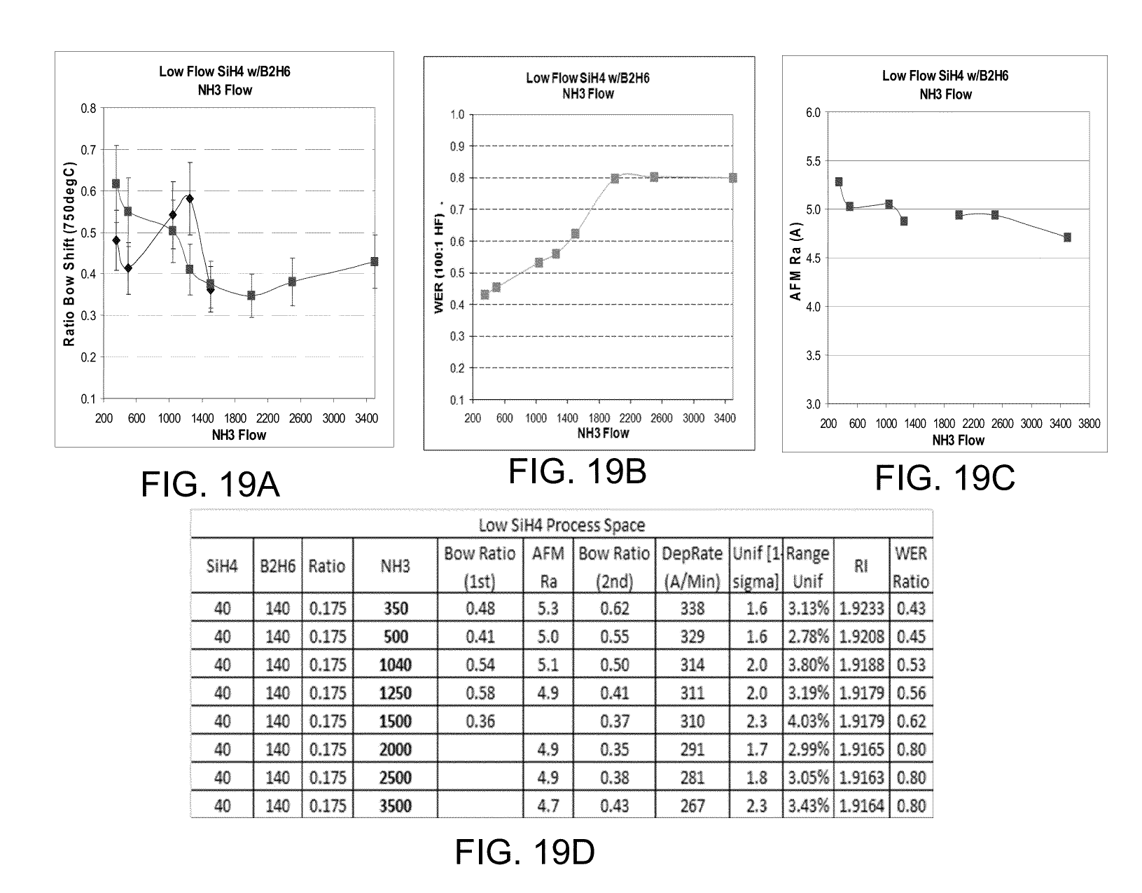

FIGS. 18 and 19 depict the influence of ammonia on a low silane process with diborane added. In the experimental results presented on these pages, the silane flow rate was 40 sccm and the diborane flow rate was 140 sccm (5% diborane source gas, i.e., 7 sccm diborane in 133 sccm carrier gas). The ammonia concentration was varied from 350 sccm up to 3500 sccm.

As shown in the FTIR plots show in FIG. 18, increasing the ammonia flow decreases two of the boron-nitrogen peaks (at about 1200 cm⁻¹ and 1380 cm⁻¹) and also decreases the silicon-nitrogen peaks (e.g., the silicon-nitrogen area around 700 cm⁻¹). The bow shift ratio is shown as a function of ammonia flow is shown in FIG. 19A. Higher ammonia flows may result in improved bow shift ratios (here as low as 0.36). It is also noted that that the ammonia concentration has a relatively strong effect on the wet etch rate with hydrofluoric acid, as shown in FIG. 19B (here as high as about 0.80). As a consequence, it is believed that films deposited with higher concentrations of ammonia might be easier to dry etch with fluorine containing etchants. Note that in conventional fabrication of vertical memory devices, the nitride-oxide stack is first dry etched to define columns containing the stack and only subsequently wet etched to selectively remove some of the silicon nitride. The surface roughness shows slight improvement with increasing ammonia flow, as depicted in FIG. 19C. FIG. 19D shows the reaction parameters and resulting film properties for the films characterized in FIGS. 19A-C.

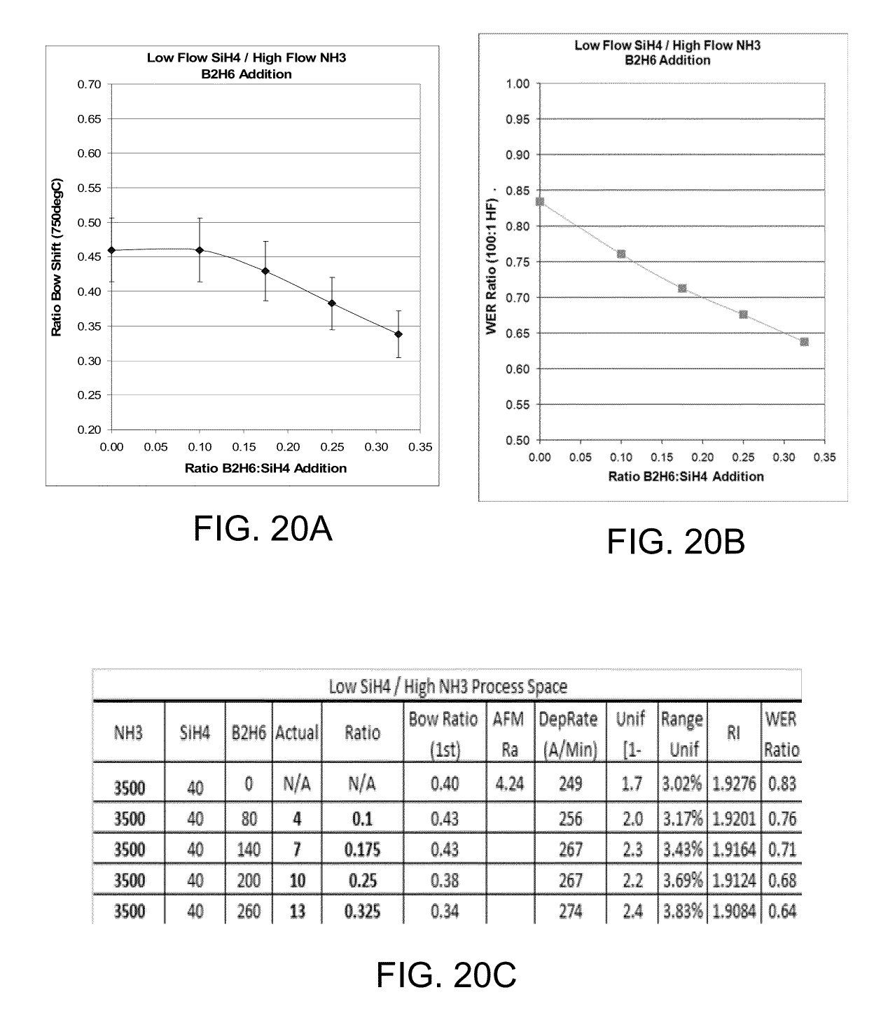

FIGS. 20A-C present data illustrating the effect of diborane concentration in a low silane process that employs high ammonia flows. Specifically, the ammonia was provided at a flow rate of 3500 sccm and silane was provided the flow rate of 40 sccm. The flow of 5% diborane source gas varied between 0 and 260 sccm. FIG. 20A illustrates the bow shift ratio as a function of diborane flow, and FIG. 20B shows the wet etch rate ratio as a function of diborane flow. Although the x-axis is labeled “Ratio B2H6:SiH4 Addition,” this axis may also be interpreted as the diborane concentration in the process gases because the amount of silane was kept constant between these samples. FIG. 20C shows the reaction parameters and resulting film properties for the films characterized in FIGS. 20A-B. Of note, increasing diborane concentration produced more stable films (e.g., films having lower bow shift ratios) having lower wet etch rates in hydrofluoric acid and lower refractive indices.

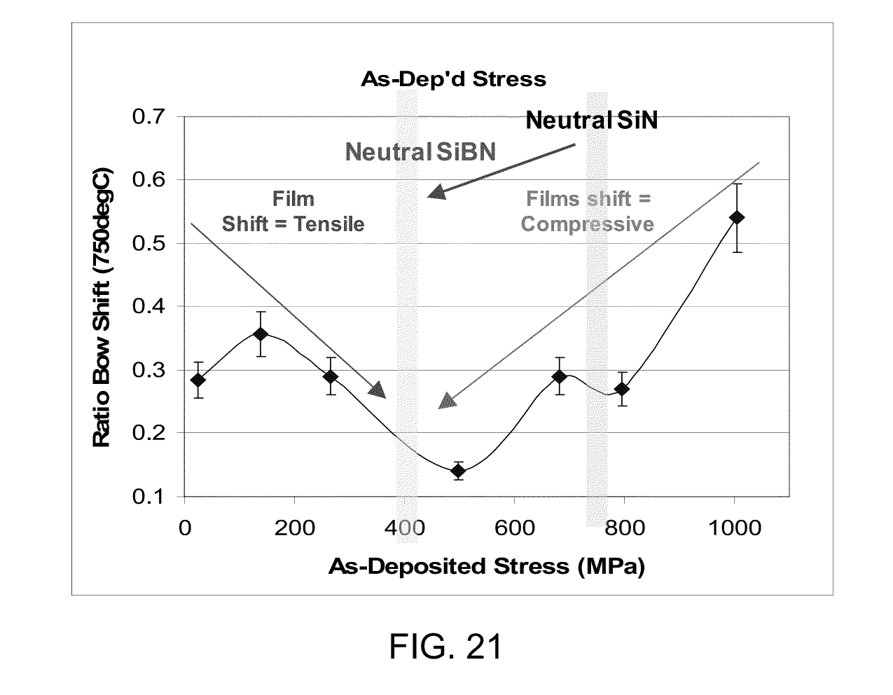

In FIG. 21, the as-deposited stress of silicon boronitride is compared to that of silicon nitride deposited by other processes described herein. Specifically, the bow shift ratio was plotted as a function of the as-deposited stress. The as-deposited stress is known to vary as a function of the composition of the materials deposited. It was found that the silicon boronitride film has a neutral point at approximately 400 MPa. This should be compared to the neutral stress of silicon nitride is about 700 MPa tensile, while the neutral stress of the silicon boronitride films is about 400 MPa tensile. As shown in the plot in FIG. 21, silicon boronitride has both a lower bow shift and lower neutral stress value than silicon nitride. Thus, it is believed that silicon boronitride is more stable to high temperature thermal treatments than silicon nitride.

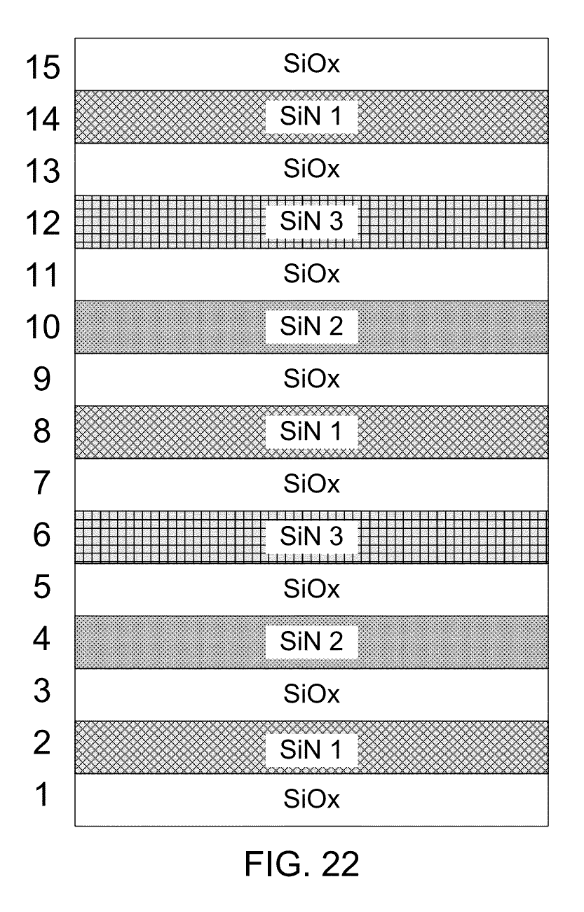

FIGS. 22-27B depict experiments conducted with large stacks of alternating oxide and nitride layers. For context, FIGS. 7-21 depicted experiments conducted with unit layers (i.e., single layers of silicon nitride or silicon boronitride). FIGS. 22-27B, in contrast, depict experiments conducted on multilayer stacks of alternating silicon oxide and silicon nitride layers. The silicon oxide employed in the stacks is a thermal oxide formed from silane as described above.

The data in FIGS. 22-26B show the effect of hot phosphoric acid on silicon nitride etching in the large stacks. The hot phosphoric acid was heated to the temperature of 158° C.

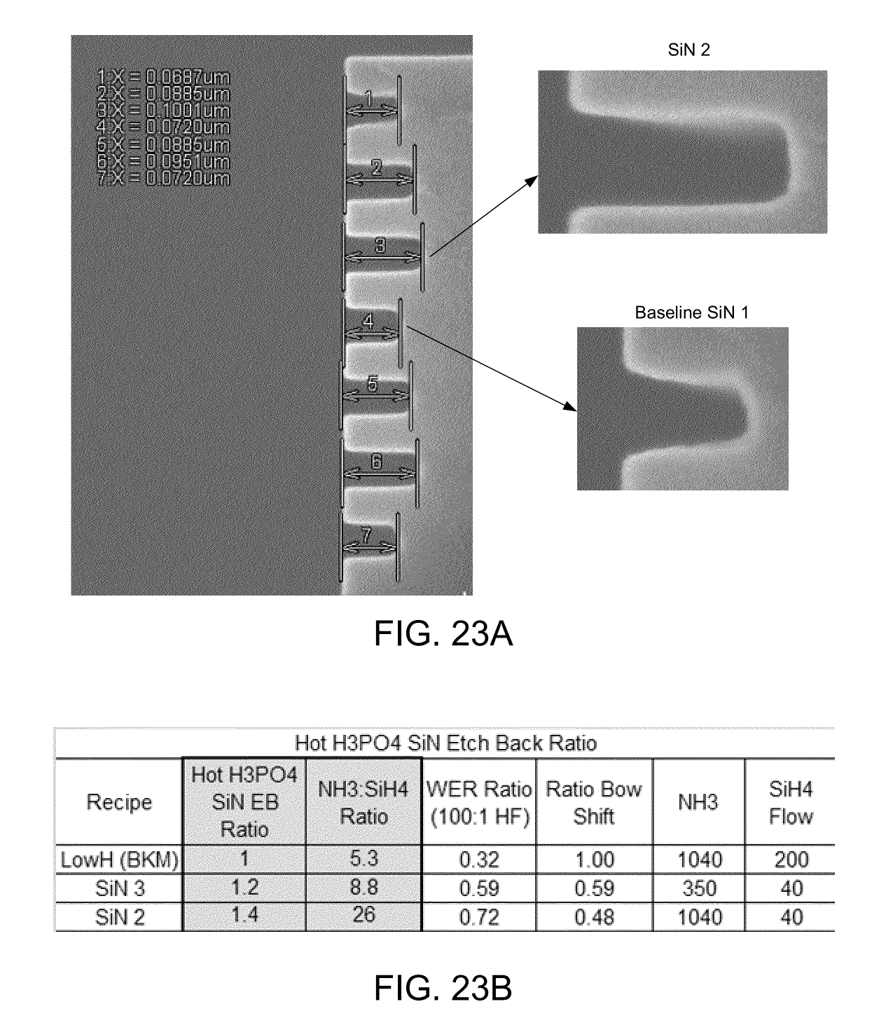

The silicon nitride employed in the stacks has different compositions at different levels. Specifically, three different compositions of silicon nitride (including silicon boronitride) were employed in each of the stacks. These different silicon nitrides were introduced in successive silicon nitride layers in the stacks as depicted in the diagram of FIG. 22. In each stack, one of the silicon nitride layers (SiN 1/LowH(BKM)) was produced by the baseline process. The idea behind using these different silicon nitride compositions in the same stack was to easily and directly compare the etch responses of the different nitride compositions. This is illustrated in the micrographs shown in FIGS. 23A-26B. As can be seen in FIG. 23A, the low silane deposited silicon nitride layers were etched more rapidly than the baseline process silicon nitride layers. Further, as between the two low silane silicon nitride layers (SiN 2 and SiN 3), the one that employed a high concentration of ammonia (SiN 2) etched the fastest.

Note that the bow shift ratio decreased with increasing etch rates. Both of these changes are desirable. For many applications, it is important to have not only a thermally stable film, but also a film that exhibits a high wet etch rate. Further, it may be desirable to be able to adjust the wet etch rate and/or bow shift to a desired value.

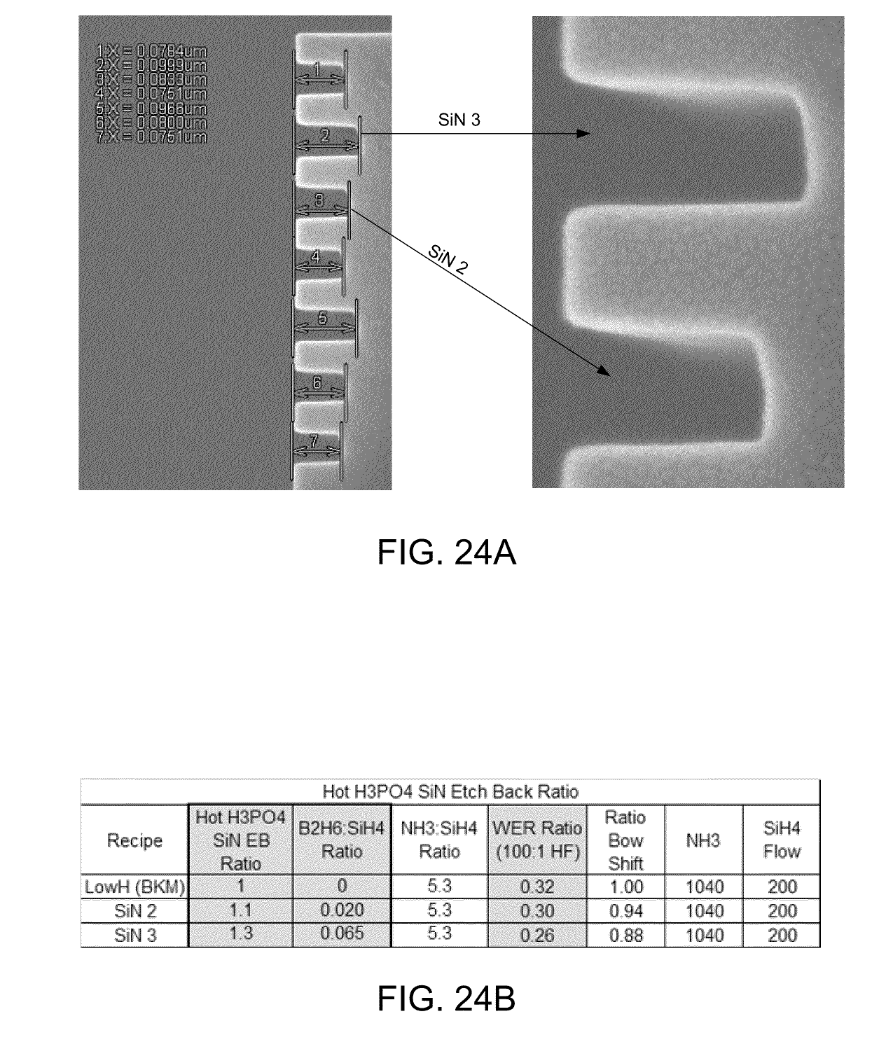

The stack considered in FIGS. 24A-B also had three different silicon nitride layers, two of which contained boron (SiN 2 and SiN 3), and one of which was the baseline silicon nitride (SiN 1). All three of the silicon nitride layers were produced from processes employing baseline amounts of silane and ammonia. However, two of the layers include boron introduced by using diborane in the process gas. One interesting observation is that the addition of diborane to the baseline process increased the etch rate of the resulting films to hot phosphoric acid but decreased the etch rate of such films in hydrofluoric acid. Thus, addition of diborane permits tailoring of the etch rates to individual wet etchants.

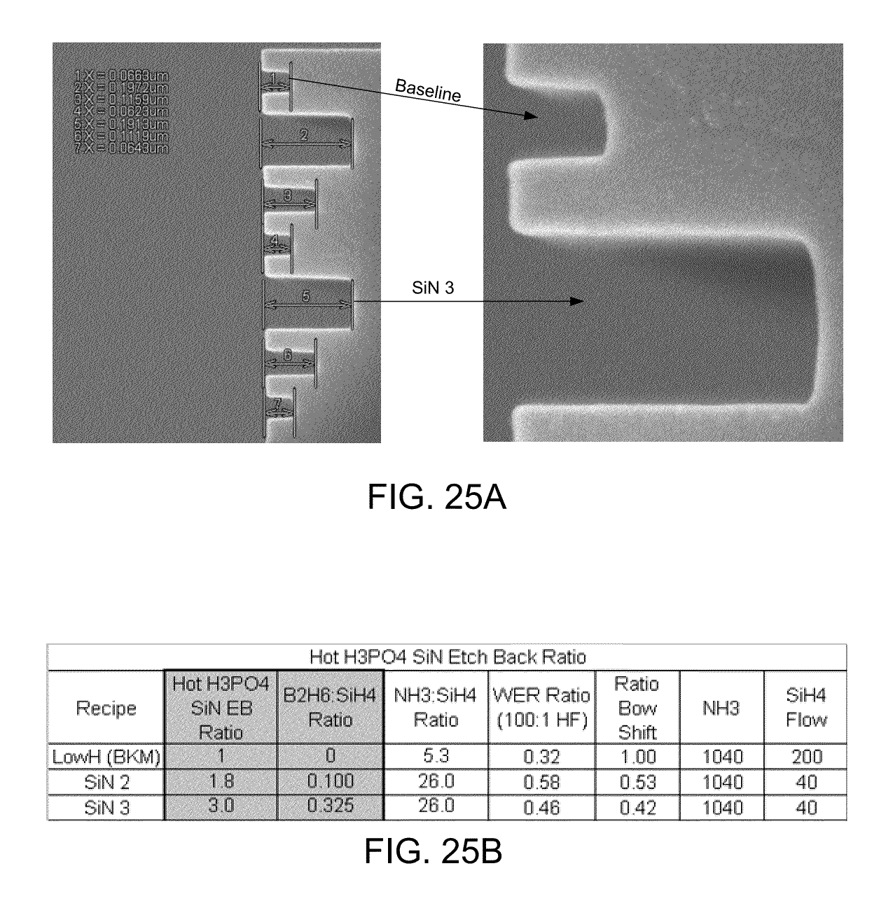

Each of the three unique nitride layer compositions used to generate the stacks and micrographs shown in FIG. 25A were produced by processes in which both the silane and diborane flow rates were varied in comparison to the compositions of the other nitride layers. The film produced with the greatest amount of diborane and a low amount of silane (SiN 3) exhibited a significantly increased etch rate in hot phosphoric acid and a markedly lower bow shift ratio.

In certain embodiments, the flow ratio range of silane flow to total diborane flow (where only about 5% of the total diborane flow is diborane, and the remaining 95% is a carrier gas) is about 0.15 to about 0.5 (SiH₄/5% B₂H₆). In certain embodiments, the flow ratio range of SiH₄ to NH₃ is about 0.02 or less. In a specific embodiment, the flow ratio between SiH₄ to NH₃ is about 0.013 or less. It should be understood that variations of the process employ boron precursors other than diborane and/or silicon hydrides other than silane, and/or nitrogen-containing gases other than ammonia or elemental nitrogen.

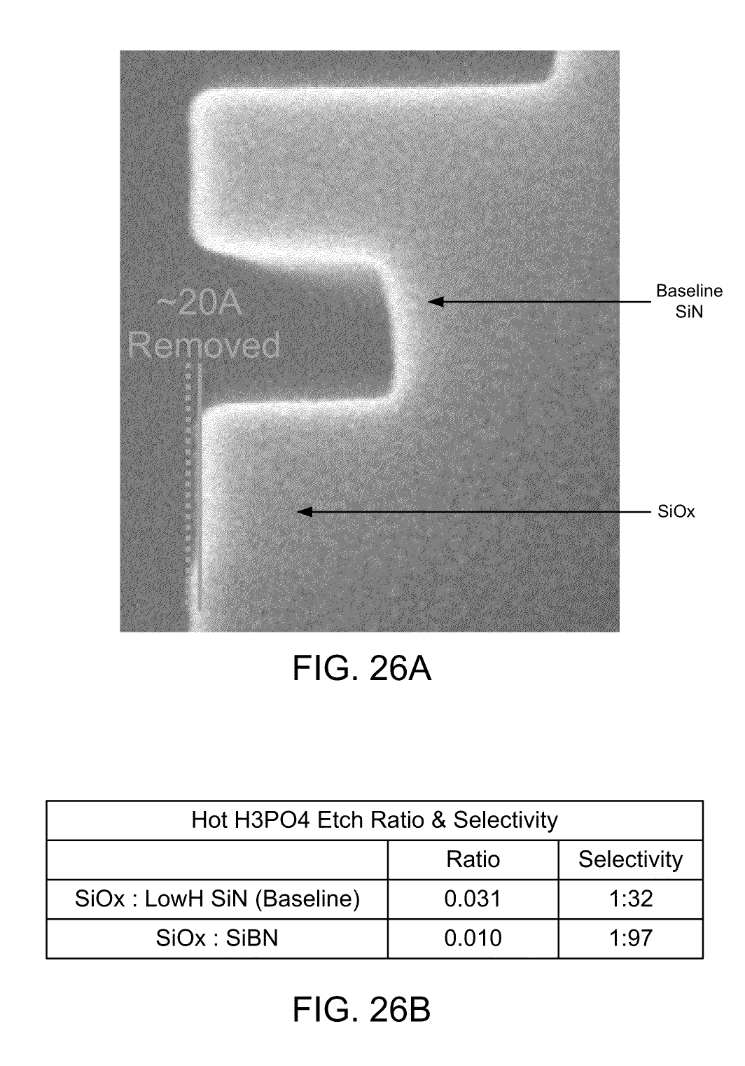

FIG. 26A shows a micrograph of a silicon oxide/silicon nitride stack that was etched in hot phosphoric acid (heated to 158° C.). Two types of silicon nitride layers were used including a baseline silicon nitride and a silicon nitride produced with diborane. FIG. 26A illustrates that a very small amount (e.g., less than 20 Å) of silicon oxide is etched by the hot phosphoric acid. FIG. 26B shows the SiOx:SiN etch ratio and selectivity for the different layers. Notably, the silicon nitride produced with diborane advantageously had a lower SiOx:SiN etch ratio and higher selectivity as compared to the baseline silicon nitride.

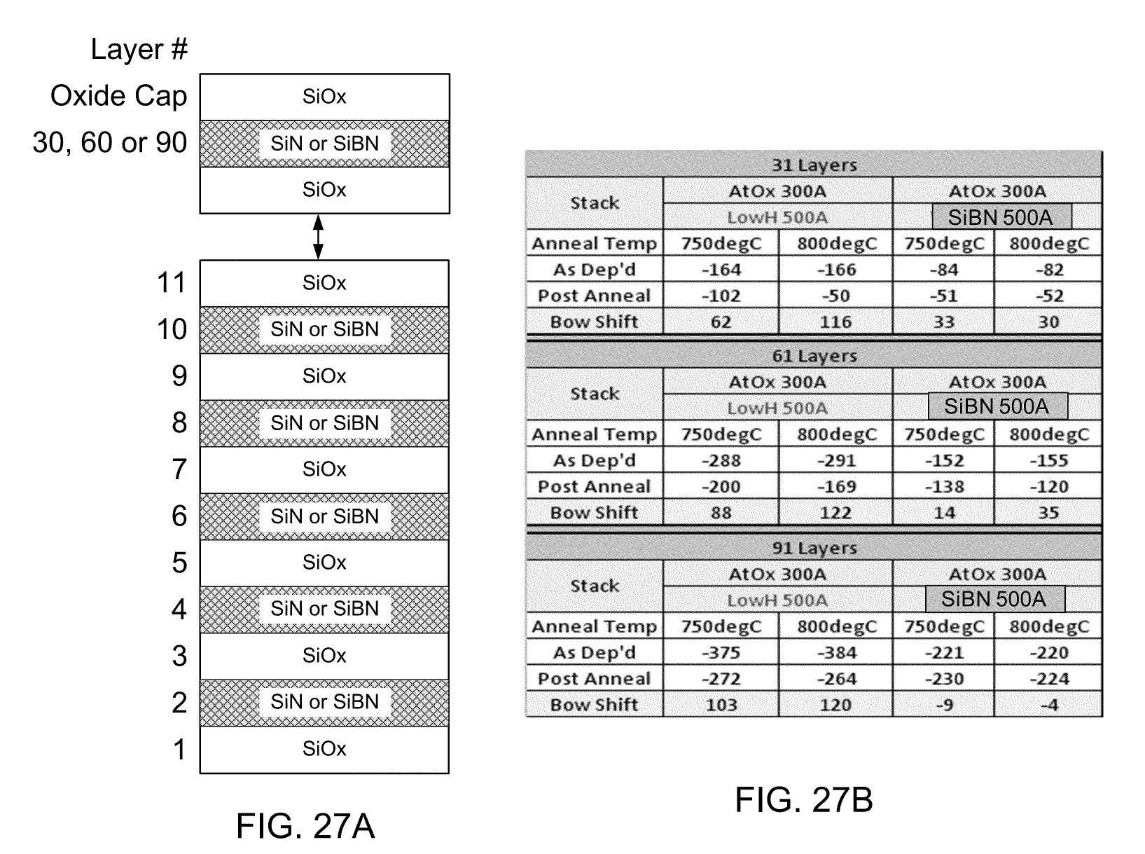

FIGS. 27A-B show how different silicon nitride layers impact bow shift in large stacks subjected to high processing temperatures. Six stacks were created as shown in FIG. 27A, three employing the baseline process silicon nitride and three employing the best performing boron-containing nitride. Specifically, the boron containing nitride was formed using the following ratio of process gasses: SiH₄/5% B₂H₆=0.29 and SiH₄/NH₃=0.011. For each of these nitrides/boronitrides, stacks of 31, 61, and 91 layers were produced. Each of the stacks had alternating layers of thermal oxide and the relevant silicon nitride or silicon boronitride. The oxide layers were deposited to a thickness of 300 Å and the nitride or boronitride layers were deposited to a thickness of 500 Å. The resulting stacks were subjected to annealing temperatures of 750 to 800° C. for two hours. The numbers of layers in the stacks (31, 61, and 91) were chosen to approximate successive future generations of devices.

The data presented in FIG. 27B show that the stacks with the boronitride layers (columns 4 and 5) exhibited remarkably little bow shift and stability in the face of aggressive thermal processing as compared to the stacks produced using the baseline process (columns 2 and 3). The boronitride exhibited stability at both 750° and 800° C., with bow shifts of less than about 40 micrometers in each stack. The silicon nitride layers, in contrast, exhibited a marked temperature sensitivity, with bow shifts ranging between about 60-125 micrometers, and significantly higher bow shift at the higher temperature.

With a 31 layer stack and the baseline nitride, a 62 micrometer bow shift was observed with a 750° C. anneal. With the same 31 layer stack, the bow shift essentially doubled when the anneal temperature was raised to 800° C. In contrast, the 30 layer stacks including boronitride had a much smaller bow shift (about 33 micrometers), which was essentially temperature invariant. Similar results were observed with the 61 and 91 layer stacks.

FIGS. 23A-27B demonstrate that one can dial-in chosen etch rates for a given stack. With different nitrides or boronitrides one can vary the cavity depth in the stack while exposing the layers to the same wet bulk chemistry. In practice, the designer can specify different levels of boron, silicon-containing reactant and nitrogen-containing reactant to be used when forming the individual layers in order to customize the cavity size as a function of stack position. Different cavities will allow the designer more flexibility in designing the semiconductor products.

FIG. 28 shows a micrograph of a fishbone structure that is likely to be used in the fabrication of semiconductors. The silicon nitride is etched away to form cavities/recesses.

What is claimed is:

1. A method for forming a silicon nitride film on a substrate in a plasma-enhanced chemical vapor deposition apparatus, the method comprising:
flowing a silicon-containing reactant, a nitrogen-containing reactant, and a boron-containing reactant through the plasma-enhanced chemical vapor deposition apparatus containing the substrate, wherein the flowing is conducted such that the ratio of flow rates of the silicon-containing reactant to the nitrogen-containing reactant is about 0.02 or less;
generating or maintaining a plasma in the plasma-enhanced chemical vapor deposition apparatus; and
depositing the silicon nitride film on the substrate.

2. The method of claim 1, wherein the silicon-containing reactant is selected from the group consisting of silane, disilane, trisilane or an alkyl silane.

3. The method of claim 1, wherein the nitrogen-containing reactant is selected from the group consisting of ammonia, hydrazine or nitrogen.

4. The method of claim 1, wherein the boron-containing reactant is selected from the group consisting of diborane and trimethyl borate.

5. The method of claim 4, wherein the flowing is conducted by flowing diborane at a rate of about 4 to 15 sccm.

6. The method of claim 4, wherein the silicon-containing reactant is silane and the boron-containing reactant is diborane, and wherein the flowing is conducted such that the ratio of flow rates of the silane to diborane is about 3 to 20.

7. The method of claim 6, further comprising flowing diborane to the apparatus in an inert gas carrier.

8. The method of claim 1, wherein the flowing is conducted with the addition of a flowing inert gas.

9. The method of claim 8, wherein the inert gas is nitrogen.

10. The method of claim 1, wherein the generating and maintaining the plasma is conducted using low frequency and high frequency power and wherein the low frequency power is provided at about 0 to 300 Watts per 300 mm wafer.

11. The method of claim 10, wherein the low frequency power is provided at or below about 75 Watts per 300 mm wafer.

12. The method of claim 10, wherein the high frequency power is provided at about 100 to 750 Watts per 300 mm wafer.

13. The method of claim 1, wherein the pressure in the apparatus is maintained between about 0.5 and 8 Torr while depositing the silicon nitride film on the substrate.

14. The method of claim 1, wherein the depositing deposits the silicon nitride film on the substrate to a thickness of between about 10 and 100 nm.

15. The method of claim 1, wherein the silicon nitride film etches at a rate of at least about 20 Ångstroms per minute when exposed to aqueous hydrofluoric acid provided in a volume ratio of 100 units of water to 1 unit standard 50% hydrofluoric acid at 20° C.

16. The method of claim 1, further comprising:
selecting an amount of internal stress for the silicon nitride film; and
selecting process parameters for depositing the silicon nitride film with the amount of internal stress.

17. The method of claim 1, wherein the depositing is conducted under conditions that produce the silicon nitride film with tensile internal stress.

18. The method of claim 17, wherein tensile internal stress is between about 400 and 600 MPa.

19. The method of claim 1, wherein the silicon nitride film comprises between about 1 and 15 atomic percent boron.

20. The method of claim 1, wherein the silicon nitride film has an average roughness of less than about 6 Å as measured on the substrate.

21. The method of claim 20, wherein the silicon nitride film has an average roughness of less than about 4.5 Å as measured on the substrate.

22. The method of claim 1, further comprising heating the substrate with deposited silicon nitride film to a temperature of at least about 400° C.

23. The method of claim 1, further comprising forming a stack comprising alternating layers of an oxide and the deposited silicon nitride film.

24. The method of claim 23, wherein the stack contains at least about 10 layers of the silicon nitride film.

25. The method of claim 24, wherein the stack contains at least about 50 layers of the silicon nitride film.

26. The method of claim 23, further comprising wet etching silicon nitride layers from the stack to form a fishbone shaped structure having recesses.

27. The method of claim 26, further comprising forming a vertical memory device using the fishbone shaped structure.

28. The method of claim 26, further comprising forming capacitors at least partially in the recesses formed by wet etching silicon nitride.

29. A method for forming a film stack including a silicon nitride film and a second film on a substrate, the silicon nitride film having a different material composition from the second film, the method comprising:
(a) depositing the silicon nitride film on the substrate by plasma-enhanced chemical vapor deposition while flowing a silicon-containing reactant, a nitrogen-containing reactant, and a boron-containing reactant through the plasma-enhanced chemical vapor deposition apparatus containing the substrate, wherein the silicon nitride film has a thickness of between about 10 and 100 nm;
(b) depositing the second film on the silicon nitride film, wherein the second film has a thickness of between about 10 and 100 nm; and
(c) repeating (a) and (b) at least twice to form the film stack.

30. The method of claim 29, wherein depositing the silicon nitride film is conducted such that the ratio of flow rates of the silicon-containing reactant to the nitrogen-containing reactant is about 0.02 or less.

31. The method of claim 29, wherein the second film is a silicon oxide film.

32. The method of claim 31, wherein the silicon oxide film is formed by a thermal process.

33. The method of claim 31, wherein (c) comprises repeating (a) and (b) at least 10 times to form the film stack.

34. The method of claim 33, further comprising wet etching the silicon nitride film from the stack to form a fishbone shaped structure having recesses.

35. The method of claim 34, further comprising forming a vertical memory device using the fishbone shaped structure.

36. The method of claim 34, further comprising forming capacitors at least partially in the recesses formed by wet etching silicon nitride.

37. The method of claim 29, further comprising:
applying photoresist to the substrate;
exposing the photoresist to light;
patterning the resist with a pattern and transferring the pattern to the substrate; and
selectively removing the photoresist from the substrate.

38. A plasma-enhanced chemical vapor deposition apparatus configured to deposit a film stack on a substrate, the apparatus comprising:
a process station;
a first reactant feed for supplying a silicon-containing reactant to the process station;
a second reactant feed for supplying a co-reactant to the process station;
a plasma source; and
a controller configured to control the apparatus to maintain a plasma and process gas flow conditions, the controller comprising instructions for
(a) depositing a silicon nitride film on the substrate by plasma-enhanced chemical vapor deposition while flowing the silicon-containing reactant, a nitrogen-containing reactant, and a boron-containing reactant through the plasma-enhanced chemical vapor deposition apparatus containing the substrate, wherein the silicon nitride film has a thickness of between about 10 and 100 nm; and
(b) depositing the second film on the silicon nitride film, wherein the second film has a thickness of between about 10 and 100 nm.

39. The apparatus of claim 38, wherein the controller further comprises instructions for (c) repeating (a) and (b) at least twice to form the film stack.

40. The apparatus of claim 39, wherein the instructions for (c) comprise instructions for repeating (a) and (b) at least 10 times to form the film stack.

41. The apparatus of claim 38, wherein the plasma source is a capacitively-coupled plasma source.

42. The apparatus of claim 38, wherein the controller instructions for depositing the silicon nitride film on the substrate comprise instructions for providing a ratio of flow rates of the silicon-containing reactant to the nitrogen-containing reactant is about 0.02 or less.

43. The apparatus of claim 38, wherein the second film is a silicon oxide film.

44. The apparatus of claim 43, wherein the controller instructions for depositing the silicon oxide film on the substrate comprise instructions for forming the silicon oxide film by a thermal process.

45. The apparatus of claim 38, wherein the boron-containing reactant is diborane and the controller is configured to flow the diborane into the process station at a rate of about 4 to 15 sccm.

46. The apparatus of claim 38, wherein the boron-containing reactant is diborane, wherein the silicon-containing reactant is silane, and wherein controller is configured to flow the silane and diborane at a ratio of flow rates of the silane to diborane of about 3 to 20.

47. The apparatus of claim 38, wherein the controller further comprises instructions for generating and maintaining a plasma using the plasma source.

48. The apparatus of claim 47, wherein the instructions for generating and maintaining a plasma comprise instructions for generating low frequency and high frequency power and with the low frequency power provided at or below about 150 Watts per 300 mm wafer.

49. The apparatus of claim 48, wherein instructions for generating low frequency and high frequency power comprise instructions for generating the high frequency power at about 100 to 750 Watts per 300 mm wafer.

50. The apparatus of claim 38, wherein the controller further comprises instructions for maintaining a pressure of between about 0.5 and 8 Torr in the process station while depositing the silicon nitride film on the substrate.

51. A system, comprising the apparatus of claim 38 and a stepper tool.
